(19) United States
(12) Patent Application Publication
(10) Pub. No.: US 2011/0140070 A1
(43) Pub. Date: Jun. 16, 2011

(54) THREE-DIMENSIONAL SEMICONDUCTOR DEVICE AND METHODS OF FABRICATING AND OPERATING THE SAME

(76) Inventor: Sung-Dong Kim, Gyeonggi-do (KR)

(21) Appl. No.: 13/059,059

(22) PCT Filed: Sep. 25, 2008
(86) PCT No.: PCT/KR08/05688

§ 371 Date: Feb. 14, 2011

(30) Foreign Application Priority Data
Aug. 14, 2008 (KR) 10-2008-007688
Sep. 23, 2008 (KR) 10-2008-0093453

(51) Int. Cl. H01L 27/26

(52) U.S. Cl. 257/5; 257/E27.002

(57) ABSTRACT

Provided are three-dimensional semiconductor devices and methods of fabricating and operating the same. A device includes a connection node interposed between first and second nodes, a semiconductor pattern connected to the connection node, a plurality of memory elements connected to the semiconductor pattern, word lines connected to the memory elements, and a control electrode disposed opposite the semiconductor pattern. The control electrode selectively controls an electrical connection between the connection node and the memory element, thereby preventing an un-intended current path in a cross-point 3D memory device.

### TECHNICAL FIELD

The present invention relates to a semiconductor device and methods of fabricating and operating the same.

### BACKGROUND ART

In order to enable good performance and low price at consumers' request, it is necessary to increase the integration density of semiconductor devices. Above all, since the integration density of memory semiconductor devices significantly affects a product price, it is required to increase the integration density of the memory semiconductor devices. In the case of a typical two-dimensional or planar semiconductor memory device, since its degree of integration is largely determined by an area occupied by a unit memory cell, techniques used to form fine patterns have an effect on the integration degree and, therefore, the device cost. However, since expensive equipment is required for pattern miniaturization, even if the integration degree of a two-dimensional semiconductor memory device is increased, the semiconductor device is still under certain restrictions.

### DISCLOSURE OF INVENTION

### Technical Problem

The present invention is directed to a three-dimensional (3D) memory device, which can prevent an unintended current path in a cross-point cell array structure, and a method of operating the same.

The present invention is also directed to a 3D memory device, which can provide an increased bit number per area, and a method of operating the same.

The present invention is further directed to a 3D memory device in which various voltages may be separately applied to three-dimensionally arranged interconnection lines and a method of fabricating the same.

### Technical Solution

According to exemplary embodiments, a memory device includes: a connection node disposed between a first node and a second node; a semiconductor pattern coupled to the connection node; a plurality of memory elements, each memory element having a first end portion coupled to the semiconductor pattern; word lines coupled to a second end portion of the corresponding one of the plurality of memory elements; and a control electrode disposed opposite the semiconductor pattern, the control electrode configured to control electrical connections between the connection node and the memory elements.

According to other exemplary embodiments, a memory device includes: connection nodes disposed two-dimensionally on an xy-plane; semiconductor patterns coupled to the connection nodes, respectively, each semiconductor pattern having a z-directional major axis; word lines disposed three-dimensionally between the semiconductor patterns, each word line having an x-directional major axis; memory elements, each memory element having an end portion coupled to the corresponding one of the word lines and other end portion coupled to the corresponding one of the semiconductor patterns; control electrodes disposed opposite the semiconductor patterns and configured to control electrical connections between the connection node and the memory elements; and control lines having major axes crossing the word lines and configured to connect the control electrodes.

According to the above-described exemplary embodiments, since the control electrode can selectively control the electrical connection between the connection node and the memory element, an unintended current path in a cross-point type three-dimensional memory device can be inhibited. Specifically, a method of operating the memory device may include selecting one of the memory elements by applying a voltage, which is high enough to form an inversion region in a semiconductor pattern coupled to the selected memory element, to the control line, thereby connecting the semiconductor pattern to the connection node coupled thereto.

Meanwhile, the connection nodes may constitute a plurality of node strings having different x-coordinates, and each of the node strings may include connection nodes having different y-coordinates and substantially the same x-coordinate. Also, memory device may further include: switching elements disposed two-dimensionally on an xy-plane and configured to control electric connections between the connection nodes having the different y-coordinates; first nodes disposed on first sides of the node strings, respectively; and second nodes disposed on second sides of the node strings, respectively. The selection of one of the memory elements may include selectively connecting one of the first and second nodes to a connection node, which is connected to a semiconductor pattern coupled to the selected memory element, by controlling switching operations of the switching elements.

According to other exemplary embodiments, a memory device includes: a first switching element configured to control an electric connection between a first node and a connection node; a second switching element configured to control an electric connection between a second node and the connection node; a semiconductor pattern with a first end portion coupled to the connection node; and a plurality of memory elements with first end portions coupled to the semiconductor pattern.

According to other exemplary embodiments, a memory device includes: connection nodes disposed two-dimensionally on an xy-plane; semiconductor patterns coupled to the connection nodes and having z-directional major axes, respectively; gate patterns disposed two-dimensionally on xz-planes between the semiconductor patterns and having x-directional major axes, respectively; memory elements disposed between at least one of the gate patterns and the semiconductor patterns; and switching elements disposed two-dimensionally on an xy-plane and configured to control electric connections between the connection nodes having different y-coordinates.

Since an electrical connection between the connection nodes is controlled by the switching elements, the memory device according to the present exemplary embodiments can lead to an increase in bit number per area. A method of operating the memory device, as an example for this, may include a node selection operation in which switching operations of the switching elements are controlled to selectively connect one of the first and second nodes to a predetermined connection node. Specifically, the node selection operation may include turning on switching elements disposed between the selected one of the first and second nodes and the selected connection node and turning off at least one of switching elements disposed between the unselected one of the first and second nodes and the selected connection node.

The method may further include a cell selection operation in which voltages of the gate patterns are controlled to selectively connect the selected connection node to a predetermined memory element. The cell selection operation may include applying a higher voltage than a threshold voltage to gate patterns disposed between the selected memory element and the selected connection node such that a voltage of the selected connection node is applied to a first end portion of the selected memory element.

According to other exemplary embodiments, a memory device may include: at least one local structure including a plurality of local lines; at least one global structure including a plurality of global lines; switching elements configured to control electric connections between the local lines and the global lines; and switching lines configured to control switching operations of the switching elements. Major axes of the local line and the global line cross each other, and a major axis of the switching line penetrates through a plane including the local line and the global line. According to the present exemplary embodiments, various voltages cab be substantially independently applied to word lines of the 3D semiconductor device.

### Advantageous Effects

As described above, an unintended current path can be prevented in a cross-point three-dimensional (3D) memory device, and a bit number per area can be easily increased. Furthermore, various voltages can be independently applied to word lines of a 3D memory semiconductor device.

### BRIEF DESCRIPTION OF DRAWINGS

FIG. 1 is a circuit diagram of an interconnection structure of a three-dimensional (3D) semiconductor device according to exemplary embodiments of the present invention;

FIG. 2 is a table illustrating a method of selecting an interconnection line according to exemplary embodiments of the present invention;

FIG. 3 is a circuit diagram of an interconnection structure of a 3D semiconductor device according to other exemplary embodiments of the present invention;

FIG. 4 is a table illustrating a method of selecting an interconnection line according to other exemplary embodiments of the present invention;

FIG. 5 is a perspective view of a 3D semiconductor device according to exemplary embodiments of the present invention;

FIG. 6 is a perspective view of a switching structure according to exemplary embodiments of the present invention;

FIGS. 7 through 10 are perspective views illustrating a method of fabricating a 3D semiconductor device according to exemplary embodiments of the present invention;

FIGS. 11 through 16 are diagrams illustrating methods of fabricating switching elements according to exemplary embodiments of the present invention;

FIG. 17 is a plan view illustrating a method of fabricating switching elements according to modified exemplary embodiments of the present invention;

FIGS. 22 and 23 are respectively a circuit diagram and perspective view illustrating a structure configured to prevent a sneak path, according to exemplary embodiments of the present invention;

FIGS. 24, 26, 28, 30, 32, 34, and 36 are circuit diagrams illustrating structures according to modified embodiments of the present invention;

FIGS. 25, 27, 29, 31, 33, 35, and 37 are perspective views illustrating structures according to the modified embodiments of the present invention;

FIG. 38 is a diagram illustrating unintended current paths of a typical cross-point cell array structure;

FIGS. 39 through 41 are diagrams illustrating a method of preventing an unintended current path of a 3D semiconductor device according to exemplary embodiments of the present invention;

FIGS. 42 and 43 are diagrams of a semiconductor memory device including a current path passing through a semiconductor pattern according to exemplary embodiments of the present invention;

FIG. 44 is a cross-sectional view of a magnetic memory device according to exemplary embodiments of the present invention;

FIG. 45 is a cross-sectional view of a charge-storage-type memory device according to exemplary embodiments of the present invention;

FIG. 46 is a diagram for explaining a basic structure for selective formation of a current path;

FIGS. 47 through 49 are diagrams for explaining applied structures for selective formation of a current path;

FIGS. 50 through 52 are circuit diagrams of a cell array structure for selective formation of a current path according to exemplary embodiments of the present invention;

FIG. 53 is a table for explaining a node selection operation according to exemplary embodiments of the present invention;

FIGS. 54 through 59 are cross-sectional views of 3D semiconductor devices according to exemplary embodiments of the present invention.

FIGS. 60 through 62 are diagrams for explaining an upper interconnection line of a semiconductor device according to exemplary embodiments of the present invention;

FIGS. 63 through 65 are circuit diagrams for explaining NOR-type cell array structures according to exemplary embodiments of the present invention;

FIG. 66 is a cross-sectional view of a NOR-type flash memory according to exemplary embodiments of the present invention;

FIG. 67 is a schematic block diagram of an example of a memory card including a memory device according to exemplary embodiments of the present invention;

FIG. 68 is a schematic block diagram of a data processing system including a memory system according to exemplary embodiments of the present invention; and

FIGS. 69 and 70 are cross-sectional views of a 3D phase-change memory device according to exemplary embodiments of the present invention.

### MODE FOR THE INVENTION

The objects, features, and advantages of the present invention will be apparent from the following detailed description of embodiments of the invention with references to the following drawings. However, the present invention is not limited to the exemplary embodiments disclosed below, but can be implemented in various types. Therefore, the present embodiments are provided for complete disclosure of the present invention and to fully inform the scope of the present invention to those ordinarily skilled in the art.

It will also be understood that when a layer is referred to as being “on” another layer or substrate, it can be directly on the other layer or substrate, or intervening layers may also be present. In the drawings, the thicknesses of layers and regions are exaggerated for clarity. It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. However, each embodiment described and illustrated herein includes its complementary embodiment as well.

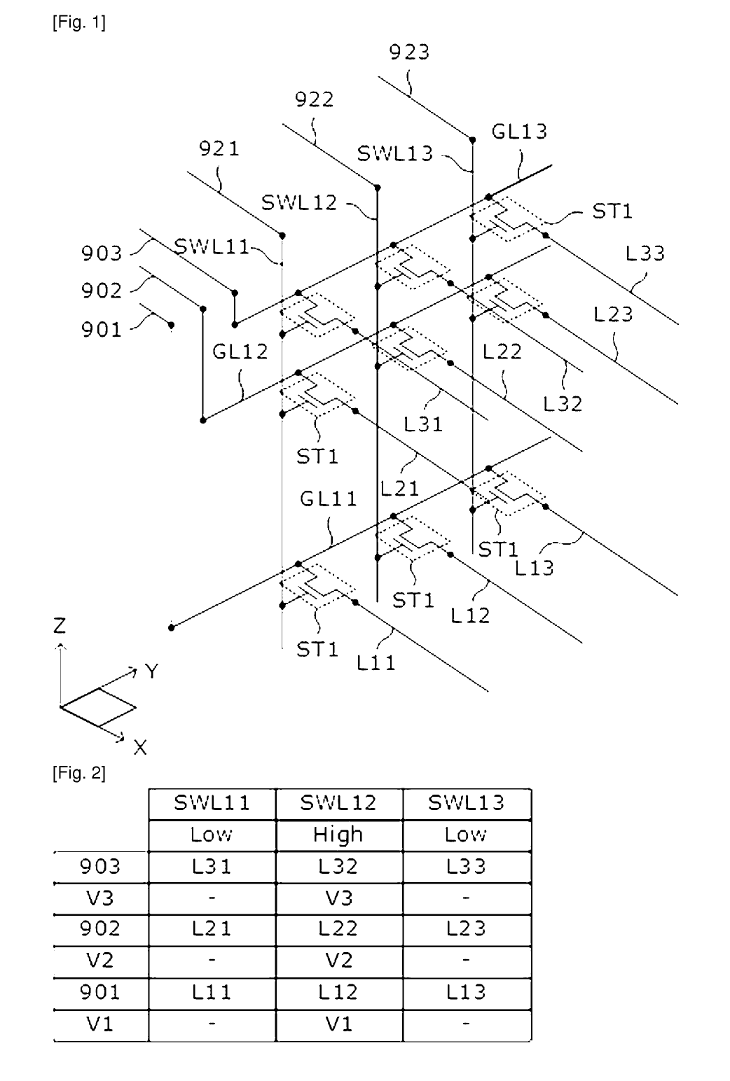

Hereinafter, for brevity, the arrangement of elements constituting a semiconductor device according to embodiments of the present invention will be described based on a three-dimensional Cartesian coordinate system. For example, as shown in FIG. 1, three orthogonal axes (x-, y-, and z-axes) may be used to define particular directions or planes. Specifically, planes parallel to both x- and y-axes may be expressed as “xy-planes”. Meanwhile, since the position of a point in a 3-dimensional space can be described using three independent coordinates, it may be interpreted that three axes (x-, y-, and z-axes) that will be used in the following description are inclined relative to the three orthogonal axes in the 3-dimensional coordinate system.

[Three-Dimensionally Arranged Interconnection Structure]

FIG. 1 is a circuit diagram of an interconnection structure of a 3D semiconductor device according to exemplary embodiments of the present invention, and FIG. 2 is a table illustrating a method of selecting an interconnection line according to exemplary embodiments of the present invention.

Referring to FIG. 1, the 3D semiconductor device according to the exemplary embodiments of the present invention may include a local line structure, which may include local lines (hereinafter, x-lines) that have a major axis along a direction of x-axis and are three-dimensionally arranged. That is, some of the x-lines may be 2-dimensionally arranged on each of a plurality of xy-planes having different z coordinates. Similarly, some of the x-lines may be 2-dimensionaly arranged on each of a plurality of xz-planes having different y coordinates. Here, an x-line, whose z and y coordinates are i and j, respectively, is illustrated with a label “Lij”. Although only 3×3 x-lines are shown for brevity, a 3-dimensional semiconductor device according to exemplary embodiments may include a larger number of x-lines.

According to some embodiments, the xy-plane may be parallel to a top surface of a substrate on which the 3-dimensional semiconductor device according to the exemplary embodiments of the present invention is integrated. However, according to other embodiments, the xy-plane may not be parallel to the top surface of the substrate.

A first global line structure may be disposed on one side of the local line structure. The first global line structure may include a plurality of first global lines GL11, GL12, and GL13 that have major axes along a direction of y-axis. The first global lines GL11 to GL13 may have different z coordinates and be disposed on a yz plane. The first global lines GL11 to GL13 may be respectively connected to first upper global inter-connections (first UGIs) 901, 902, and 903 that are electrically isolated from one another. According to some embodiments, as shown in FIG. 1, the first UGIs 901 to 903 may have different y coordinates in the same xy-plane and have major axes along the direction of x-axis. According to a modified exemplary embodiment, the first UGIs 901 to 903 may be disposed in a plurality of xy-planes having different z coordinates.

The x-lines Lij may be connected to the first global lines GL11 to GL13 by different first switching elements ST1. To do this, the number of the first switching elements ST1 may be equal to or greater than the number of the x-lines Lij. That is, each of the x-lines Lij may be electrically connected to the corresponding one of the first global lines GL11 to GL13 by at least one of the first switching elements ST1.

The first switching elements ST1 may perform switching operations (or allow or interrupt electrical connection between the x-lines Lij and the first global lines GL11 to GL13) under the control of voltages applied to first switching lines (or first vertical selection lines) SWL11, SWL12, and SWL13 that have major axes along the z direction. The first switching lines SWL11 to SWL13 may be respectively connected to first upper switching lines 921, 922, and 923, which may have different y coordinates in the same xy-plane and have major axes along the x direction. According to a modified exemplary embodiment, the first upper switching lines 921 to 923 may be disposed in a plurality of xy-planes. Meanwhile, although only three first switching lines SWL11 to SWL13 and three first global lines GL11 to GL13 are shown for brevity, the 3-dimensinoal semiconductor device according to the exemplary embodiments of the present invention may include larger numbers of first switching lines and first global lines.

According to some embodiments of the present invention, the first switching elements ST1 may include a semiconductor pattern having different impurity regions. The semiconductor pattern may be formed of at least one of semiconductor materials. For example, the semiconductor pattern may be formed of at least one selected from the group consisting of Group IV materials, Group III-V materials, an organic semiconductor material, and carbon nanostructured materials. Technical features related with the first switching elements ST1 will be described in more detail later.

### [Operation]

According to some embodiments, x-lines disposed on a single xy-plane having a predetermined z coordinate, e.g., L21, L22, and L23, may be commonly connected to the first global line having the same z coordinate as the xy-plane, i.e., GL12. Also, electrical connections between the first global lines GL11 to GL13 and the x-lines disposed on a single xz-plane having a predetermined y coordinate (e.g., L12, L22, and L32) may be allowed or interrupted under the control of the first switching line having the same y coordinate as the xz-plane, i.e., SWL12. According to some embodiments, this configuration can be used to apply selectively different voltages to x-lines disposed on the predetermined xz-plane, e.g., the x-lines L12, L22, and L32.

More specifically, when a higher voltage than a threshold voltage is applied to all the first switching lines SWL11 to SWL13, all x-lines disposed on the xy-plane including a predetermined first global line (e.g., the first global line GL12), i.e., the x-lines L21, L22, and L23, may have substantially the same electrical potential as the selected first global line GL12. Here, a threshold voltage for the first switching line refers to a critical voltage that puts the first switching element ST1 into a turn-on state.

In contrast, as shown in FIG. 2, when a higher voltage than the threshold voltage is applied to a selected first switching line (e.g., the first switching line SWL12) or a selected first upper switching line (e.g., the first upper switching line 922) and a lower voltage than the threshold voltage is applied to unselected first switching lines SWL11 and SWL13 and unselected first upper switching lines 921 and 923, only x-lines L12, L22, and L32 disposed on the xz-plane including the selected first switching line SWL12 can selectively have substantially the same electric potentials V1, V2, and V3 as the first global lines GL11 to GL13. That is, when one first switching line is selected while applying different voltages to the first global lines GL11 to GL13, the x-lines disposed on the xz-plane including the selected first switching line may have the same electrical potentials as the first global lines GL11 to GL13 and the x-lines disposed on other xz-planes may be electrically isolated from the first global lines GL11 to GL13.

Meanwhile, according to the exemplary embodiments, the x-lines Lij may be used as interconnection lines for implementing an electrical access to 3-dimensinoally arranged memory cells. For example, the x-lines Lij may serve as one of word lines, bit lines, source lines, or data lines. Several embodiments related with the x-lines Lij will be described again later.

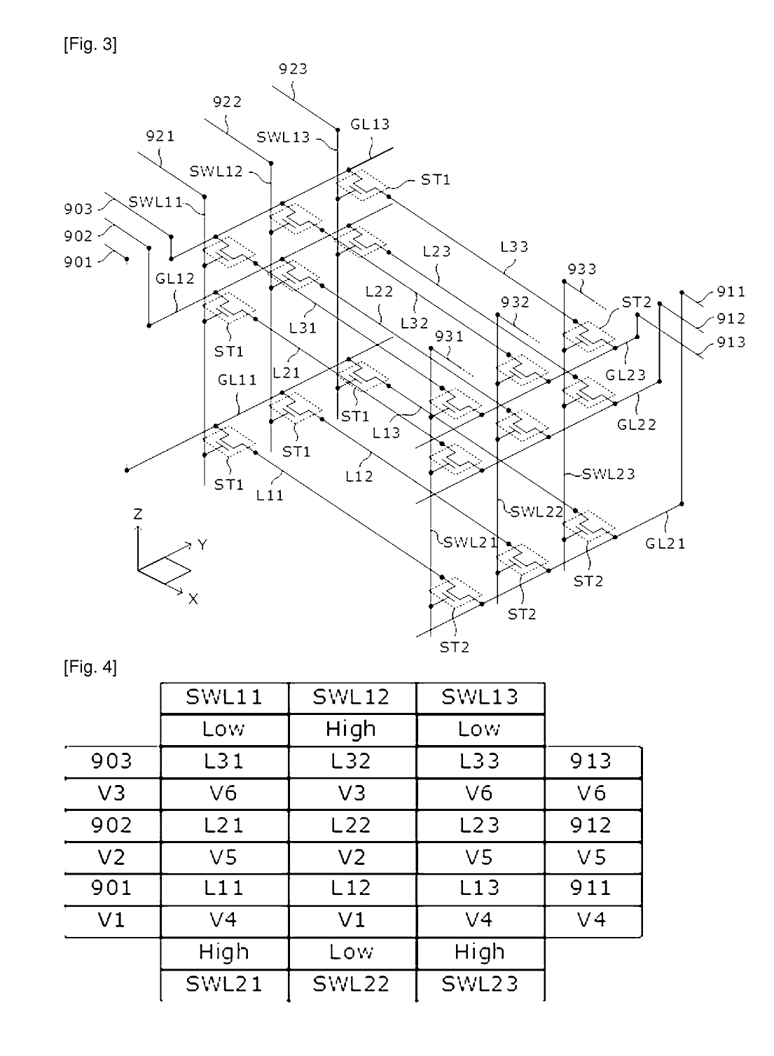

FIG. 3 is a circuit diagram of an interconnection structure of a 3-dimensional semiconductor device according to other exemplary embodiments of the present invention, and FIG. 4 is a table illustrating a method of selecting an interconnection line according to other exemplary embodiments of the present invention.

Referring to FIG. 3, the 3-dimensional semiconductor device according to the present embodiment may further include a second global line structure, which is disposed on the other side of a local line structure and includes a plurality of second global lines GL21, GL22, and GL23. Like first global lines GL11 to GL13, the second global lines GL21 to GL23 may be disposed on a yz-plane and have different z coordinates. The first and second global line structures may be respectively disposed on the yz-planes having different x coordinates.

Further, second upper global interconnections (second UGIs), which are electrically isolated from one another, may be respectively coupled to the second global lines GL21 to GL23. Also, x-lines Lij may be connected to the second global lines GL21 to GL23 by different second switching elements ST2. Switching operations of the second switching elements ST2 (or allowing or interrupting electrical connection between the x-lines Lij and the second global lines GL21 to GL23) may be controlled by voltages applied to second switching lines (or second vertical selection lines) SWL21, SWL22, and SWL23 that have major axes along the z direction. The second switching lines SWL21 to SWL23 may be connected to different second upper switching lines 931, 932, and 933, which may have different y coordinates in the same xy-plane and have major axes along the x direction.

In this case, the second global line structure, the second upper global interconnection lines 911 to 913, the second switching elements ST2, and the second switching lines SWL21 to SWL23 may have substantially the same technical features as the first global line structure, the first upper global interconnection lines 901 to 903, the first switching elements ST1, and the first switching lines SWL11 to SWL13 that are described above with reference to FIG. 1. For brevity, description on technical features overlapping those of the embodiments described with reference to FIG. 1 may be omitted will be omitted here.

### [Operation]

According to the previous exemplary embodiment, the x-lines Lij disposed on the xz-planes excluding the selected first switching line may be electrically isolated from the first global lines GL11 to GL13. Conversely, according to the exemplary embodiments described with reference to FIG. 3, the other terminals of the x-lines Lij may be connected to the second global lines GL21 to GL23 through the second switching elements ST2. As a result, two different voltages may be applied to the x-lines Lij (here, i is a constant) disposed on the same xy-plane. For example, as shown in FIG. 4, when second switching lines SWL21 and SWL23 having a different y coordinate from a selected first switching line (e.g., SWL12) are selected, that is, when a higher voltage than the threshold voltage is applied to the second switching lines SWL21 and SWL23, the x-lines disposed on the xz planes including the selected second switching lines SWL21 and SWL23 may have the same electric potentials as the second global lines GL21 to GL23.

Meanwhile, at least one of the first switching lines SWL11 to SWL13 and at least one of the second switching lines SWL21 to SWL23 may be selected. The selecting way may be variously modified considering operating principles and array structure of a semiconductor memory device. Here, “selection” refers to application of a higher voltage than a threshold voltage. For instance, a semiconductor memory device according to some embodiments of the present invention may operate based on a voltage forcing scheme. In this case, the selected first and second switching lines may be disposed on the xz planes having different y coordinates in order to prevent the x-lines Lij from being used as current paths. However, when the first and second global lines having the same z coordinate are equipotential, the selected first and second switching lines may be disposed on the xz planes having the same y coordinate. A semiconductor memory device according to other embodiments of the present invention, for example, a magnetic memory device, may operate based on a current forcing scheme. In this case, first and second switching lines disposed on the xz-plane having the same y coordinate may be selected such that the x-lines Lij can be used as current paths.

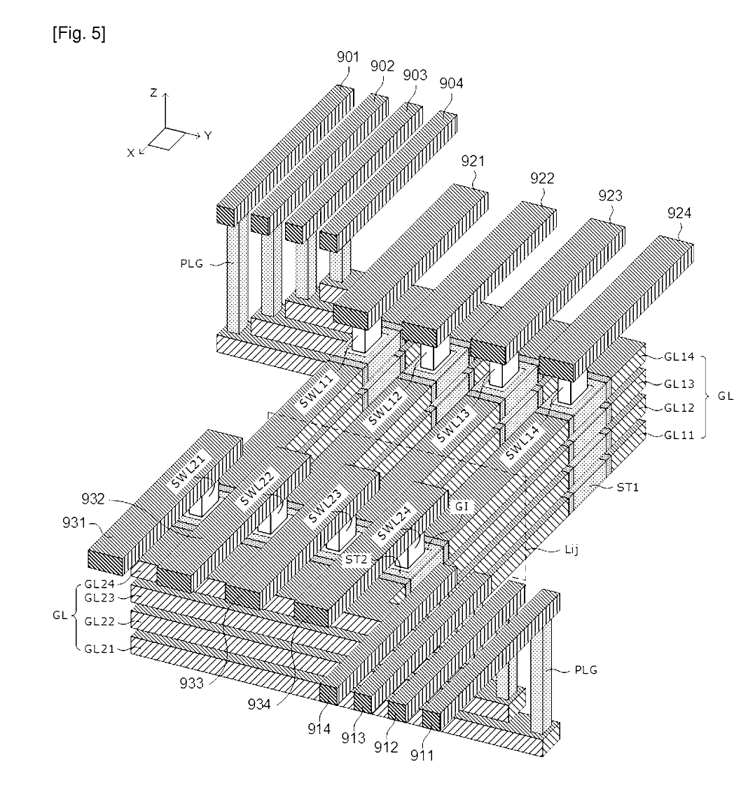

FIG. 5 is a perspective view of a 3-dimensional semiconductor device according to exemplary embodiments of the present invention. Specifically, FIG. 5 illustrates exemplarily the 3-dimensional semiconductor device described above with reference to FIG. 3. For brevity, description on technical features overlapping those of the embodiments described above may be omitted, and the ordinal terms of “first”, “second”, etc. may be omitted.

Referring to FIG. 5, a plurality of local lines (i.e., x-lines) may be 3-dimensionally arranged on a substrate (not shown). X-lines Lij (here, i is a constant) having the same height (i.e., z coordinate) may be connected to global lines GL (i.e., GL11 to GL14 and GL21 to GL24), which are electrically isolated from one another on the same xy-plane as the X-lines, through switching elements ST1 and ST2. The global lines GL may be coupled to upper global lines 901 to 904 and 911 to 914, which are electrically isolated from one another, through plugs PLG. According to a modified embodiment, the upper global lines 901 to 904 and 911 to 914 may be interposed between one of the global lines GL and the substrate.

The switching elements ST1 and ST2 are configured to selectively connect the x-lines Lij to the global line GL, and for this purpose, they may include a semiconductor pattern made of at least one of semiconductor materials. According to some embodiments, the selective connection operation of the switching elements ST1 and ST2 may be controlled depending on electrical states (e.g., electric potentials) of switching lines SWL11 to SWL14 and SWL21 to SWL24 disposed adjacent to the switching elements ST1 and ST2.

The switching lines SWL may be respectively connected to upper switching lines 921 to 924 and 931 to 934 that are electrically isolated from one another. As shown in FIG. 5, the upper switching lines 921 to 924 and 931 to 934 may be disposed over the switching lines SWL. However, according to a modified embodiment, the upper switching lines 921 to 924 and 931 to 934 may be interposed between one of the global lines GL and the substrate and connected to lower regions of the switching lines SWL.

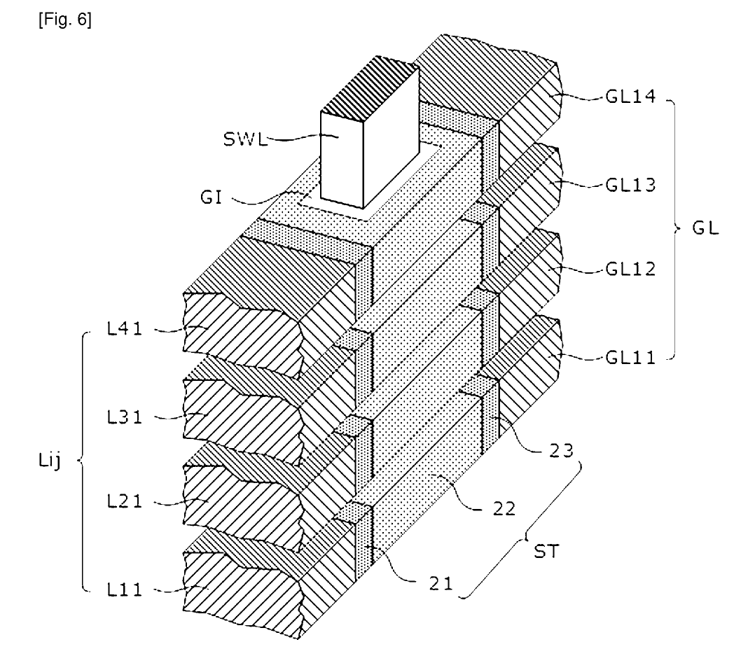

The switching line SWL and the semiconductor pattern of the switching elements ST1 and ST2 may constitute a device that provides a switching function. According to some embodiments, each of the switching elements ST1 and ST2 may be a MOS transistor, and the switching line SWL may be used as a gate electrode capable of controlling the switching operation of the switching element as described above. For example, as shown in FIG. 6, each of the switching elements ST1 and ST2 may include a semiconductor pattern 20 including regions 21, 22, and 23 of different conductivity types, which serve as a source region, a channel region, and a drain region, respectively, and the switching line SWL may be disposed to penetrate vertically semiconductor patterns 20 of a plurality of switching elements having the same x and y coordinates. In this case, as shown in FIG. 6, an insulating layer GI, which is used as a gate dielectric layer, may be interposed between the switching line SWL and the semiconductor pattern 20 of each of the switching elements ST1 and ST2. According to other embodiments, the switching line and the semiconductor pattern of the switching element may constitute a device providing a controllable rectifying function, such as a bipolar transistor or a diode.

The semiconductor pattern of the switching elements ST1 and ST2 may be formed of a semiconductor material, for example, at least one selected from the group consisting of Group IV materials, Group III-V materials, organic semiconductor materials, and carbon nanostructures. More specifically, the semiconductor pattern may be a single crystalline silicon pattern, a polycrystalline silicon pattern, or an amorphous silicon pattern, which may include impurity regions of different conductivity types. The x-lines Lij and the global lines GL may be formed of substantially the same material, which is at least one of a conductive material and a semiconductor material. The x-lines Lij and the global lines GL may be surrounded by insulating layers, which electrically insulate the x-lines Lij from the global lines GL and structurally support the x-lines Lij and the global lines GL.

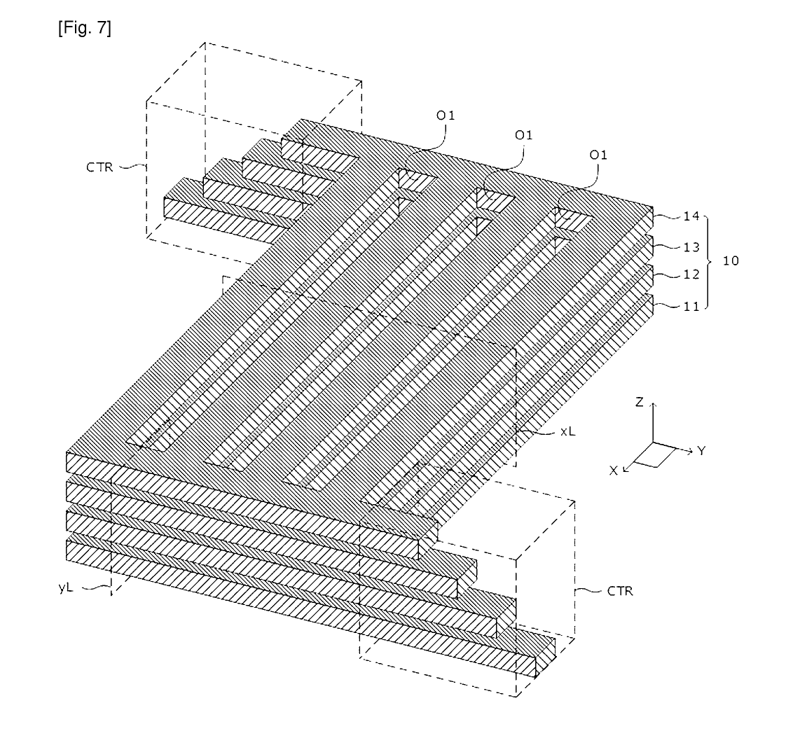

FIGS. 7 through 10 are perspective views illustrating a method of fabricating a 3-dimensional semiconductor device according to exemplary embodiments.

Referring to FIG. 7, first layers 11, 12, 13, and 14 and second layers (not shown) interposed therebetween are sequentially formed on a substrate (not shown) and patterned, thereby forming a layer structure 10 defining first openings O1 as shown. The layer structure 10 may include x-lines xL and y-lines yL, which consist of the first layers 11, 12, 13, and 14. Here, the x-lines xL have major axes parallel to the x direction, and the y-lines yL have major axes parallel to the y direction. Each of the y-lines yL may be disposed at one or both terminals of the x-lines xL and connect the x-lines xL disposed on the same xy plane.

To form subsequently a plug, a contact region CTR having a stepwise structure may be disposed on one or both sides of the y-lines yL. The stepwise structure of the contact region CTR may be formed using a patterning process that will be performed to form the first openings O1. According to a modified exemplary embodiment, the stepwise structure may be formed during another patterning process that will be performed before contact plugs are formed.

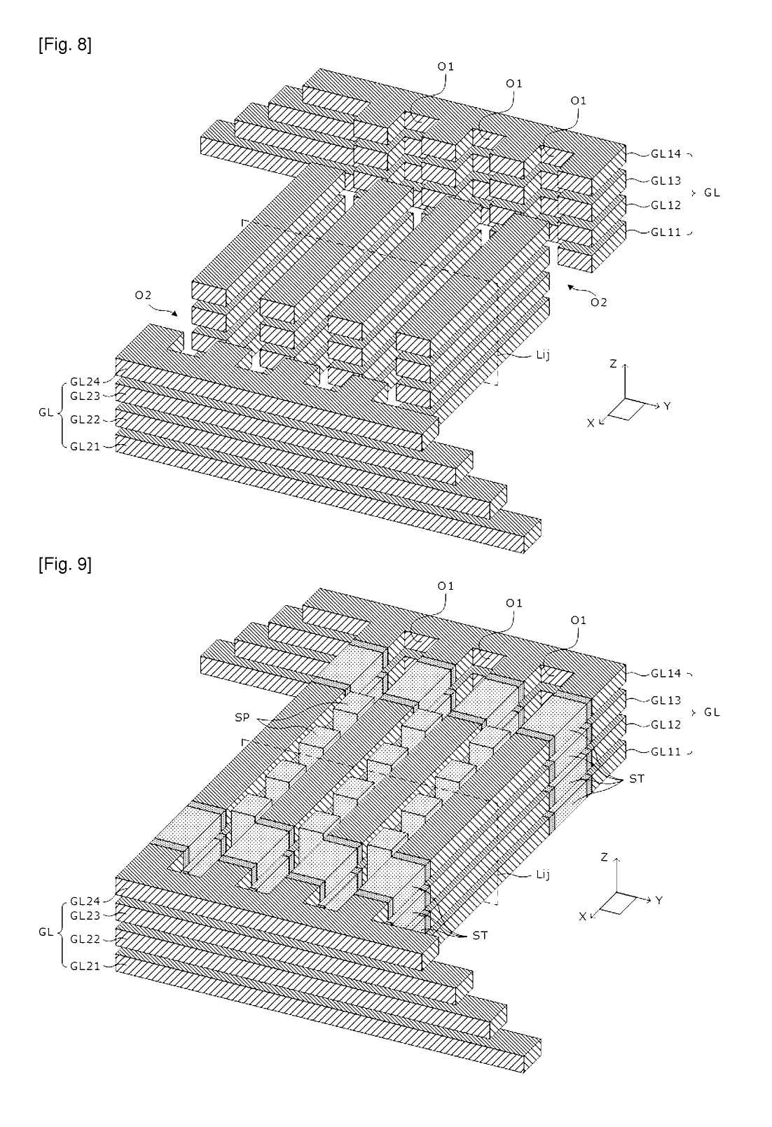

Referring to FIGS. 8 and 9, the layer structure 10 is patterned again, thereby forming second openings O2 to separate the x-lines xL from the y-lines yL. The separated x-lines xL and y-lines yL may be used as local lines and global lines described above with reference to FIG. 5. Subsequently, switching semiconductor patterns ST1 and ST2 are formed to connect the separated x-lines xL and y-lines yL.

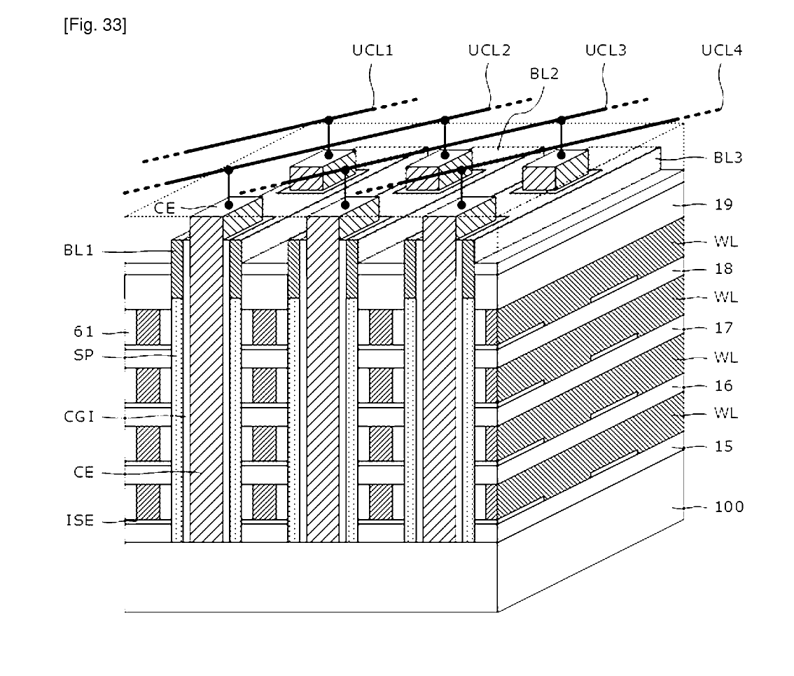

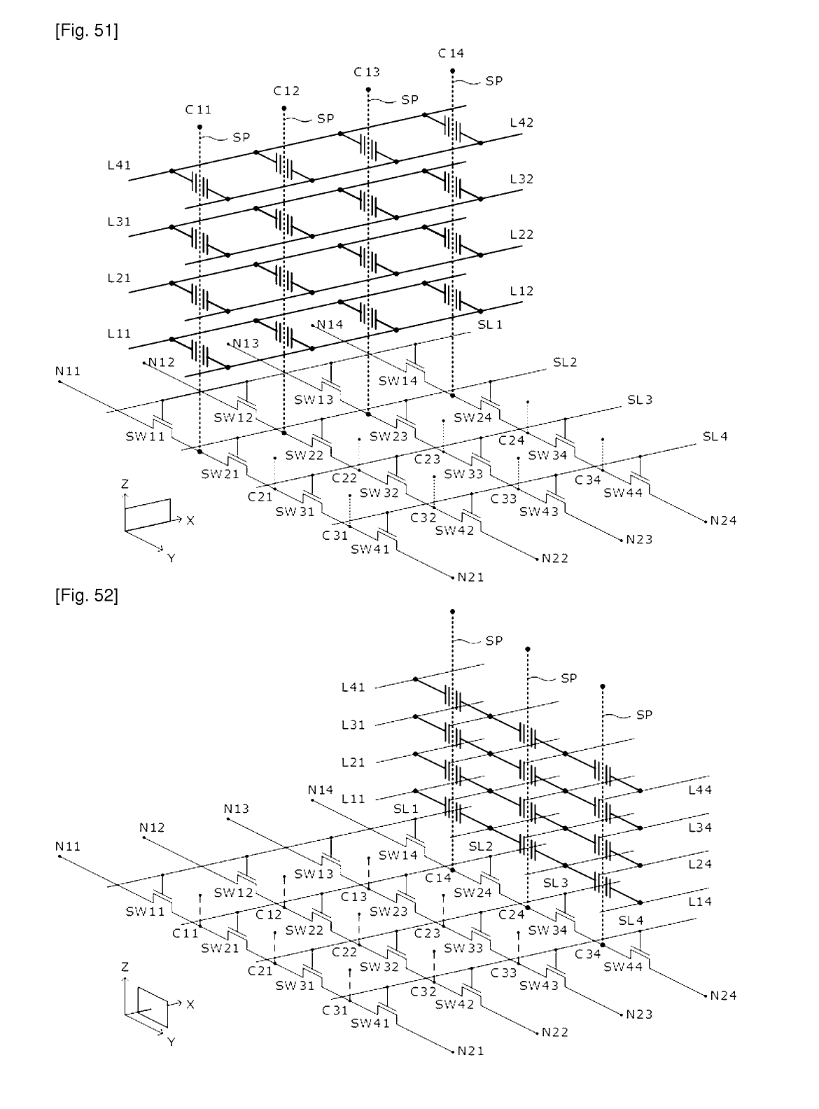

Before the second openings O2 are formed, insulating layers (not shown) filling the first openings O1 may be further formed. According to exemplary embodiments of the present invention, as shown in FIG. 9, at least one vertical semiconductor pattern SP having a major axis along a z direction may be formed in the first openings O1. The vertical semiconductor pattern SP may be formed using the process of forming the switching semiconductor patterns ST or formed using additional process operations before or after the switching semiconductor patterns ST. The process of forming the switching semiconductor patterns ST will be described later in more detail with reference to FIGS. 7 through 17, and technical features related with the vertical semiconductor patterns SP will be described later in more detail with reference to FIGS. 19 through 70.

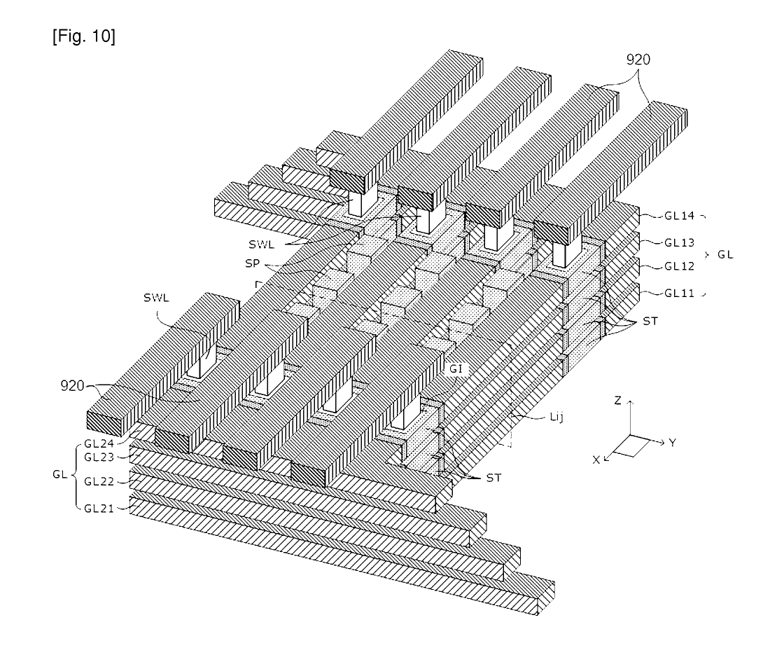

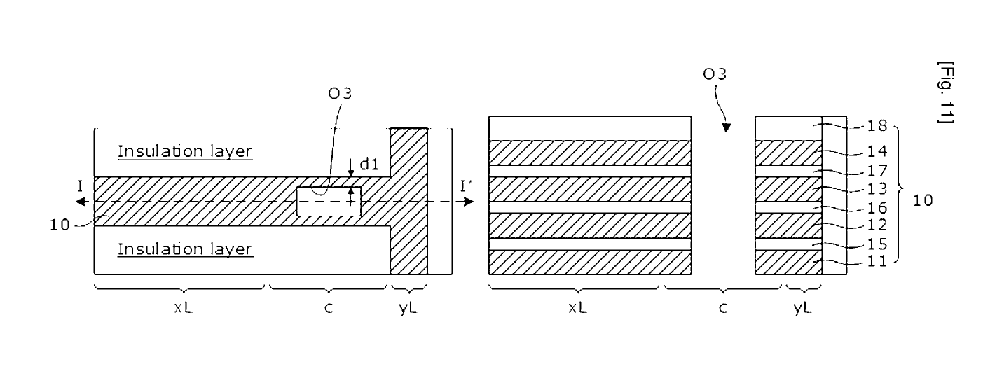

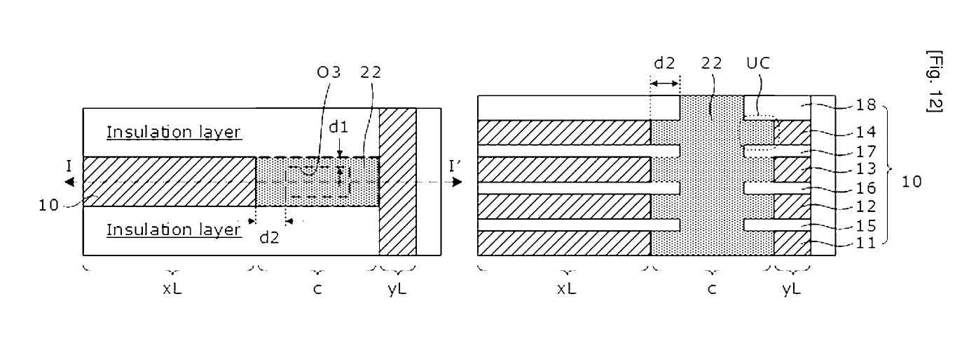

Referring to FIG. 10, switching lines SWL, which may be used to control electrical potentials of the switching semiconductor patterns ST, and upper switching lines 920 connected to the switching lines SWL are formed sequentially.

According to exemplary embodiments of the present invention, the process of forming the switching lines SWL may include forming third openings to vertically penetrate the switching semiconductor patterns ST and sequentially forming a switching gate insulating layer GI and the switching line SWL in the third opening. This process will be described later in more detail.

Thereafter, as shown in FIG. 5, plugs PLG and upper global lines 901 to 904 may be further formed to be connected to the y-lines yL. According to some embodiments, the plugs PLG may be formed using the process of forming the switching lines SWL, and the upper global lines 901 to 904 may be formed using the process of forming the upper switching lines 920.

According to a modified exemplary embodiment, the upper switching lines (not shown) may be formed before forming the layer structure 10. In this case, the upper switching lines 920 may be interposed between the substrate and the layer structure 10.

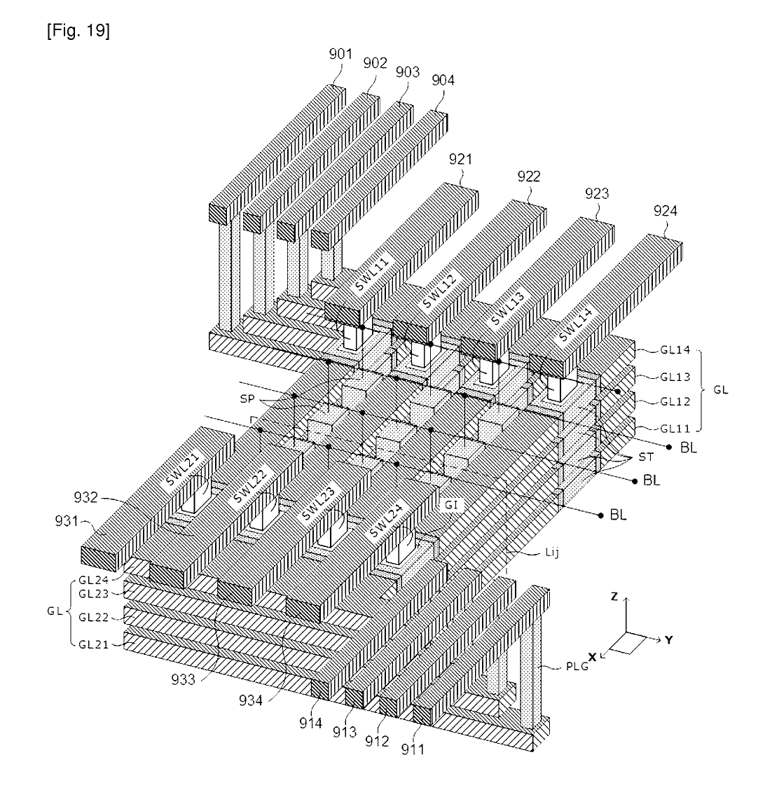

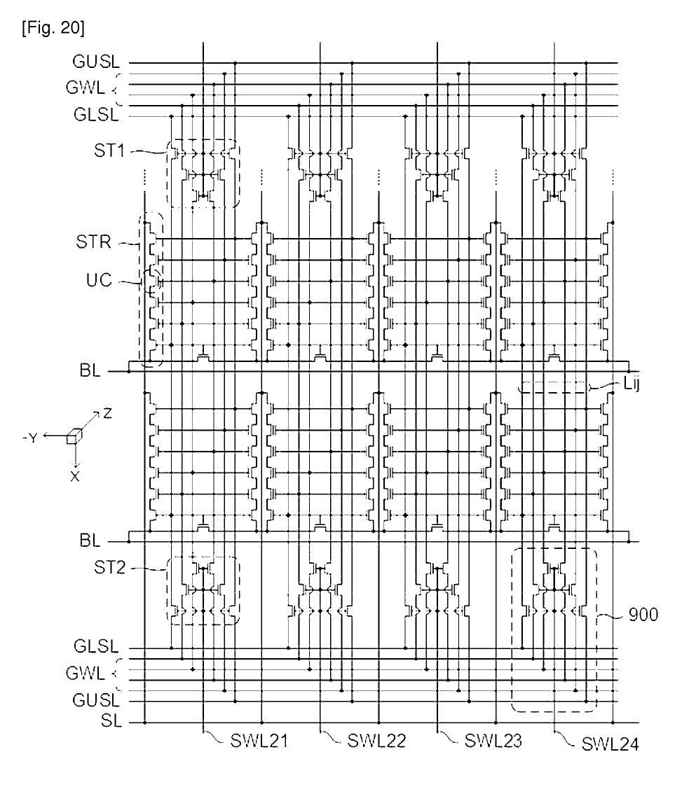

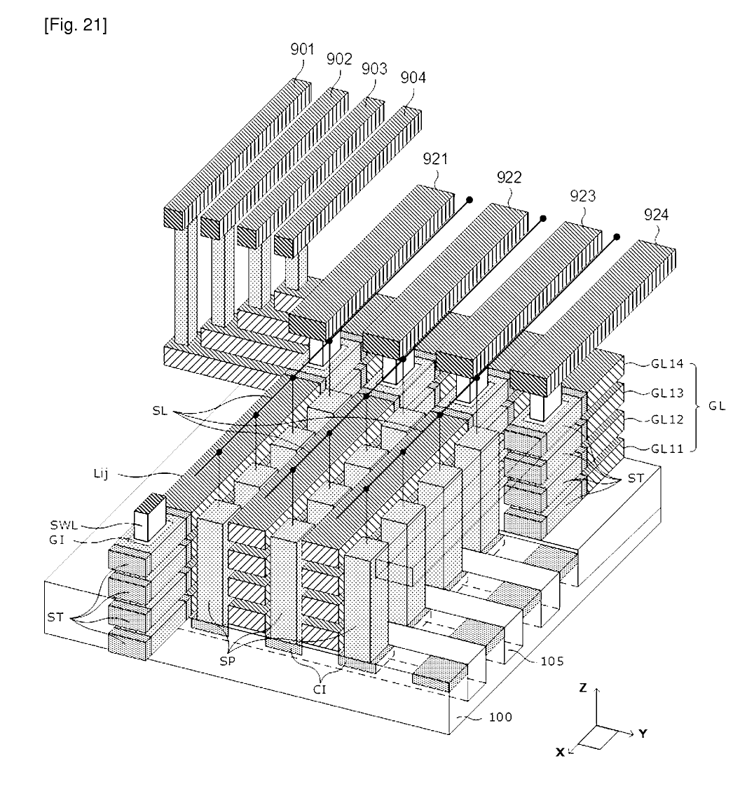

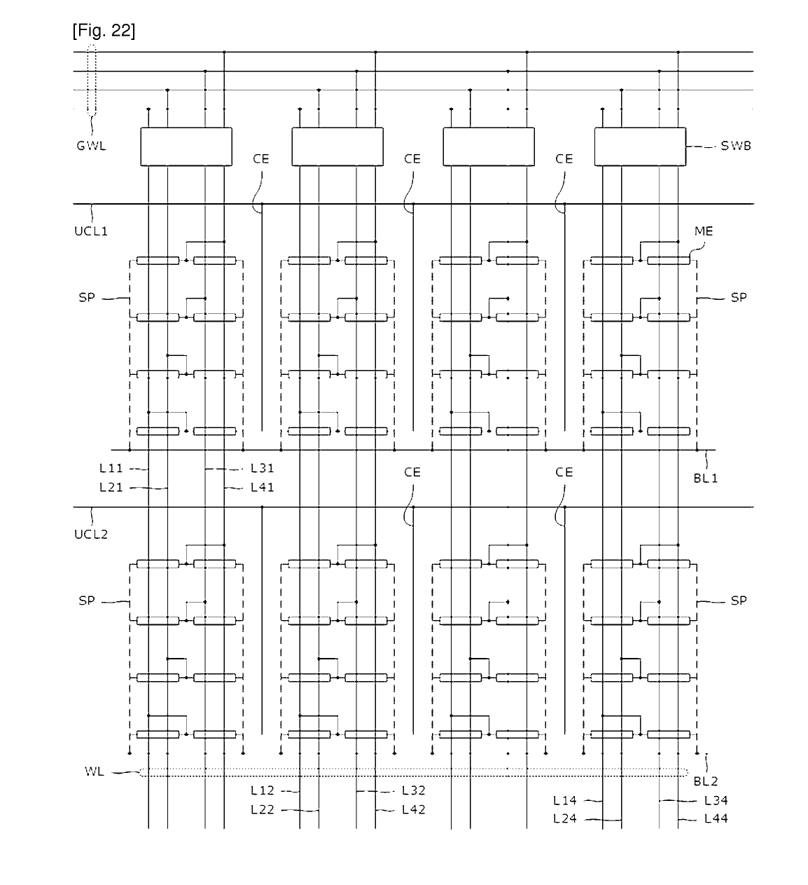

According to another modified exemplary embodiment, at least one interconnection line electrically connected to the vertical semiconductor patterns SP, a control electrode facing the vertical semiconductor pattern SP, and an upper control line connected to the control electrode may be further formed. The interconnection line may have an x- or y-directional major axis and it serves as a bit line or a source line, which may control electrical connections to the memory cells. The control electrode may have a z-directional major axis and be formed to face the vertical semiconductor pattern SP. In this case, the control electrode may control an electrical potential of the vertical semiconductor pattern SP, and thus, a selective formation of a current path is possible. As a result, the control electrode may enable the prevention of unintended current paths in 3-dimensional memory cells. Technical features related with the control electrode and the upper control line will now be described later in more detail with reference to FIGS. 22 through 45, 49, 63, 64, 69, and 70. In this case, the control electrode may be formed using a process of forming the plugs PLG, and the upper interconnection line and the upper control line may be formed using the upper global lines 901 to 904.

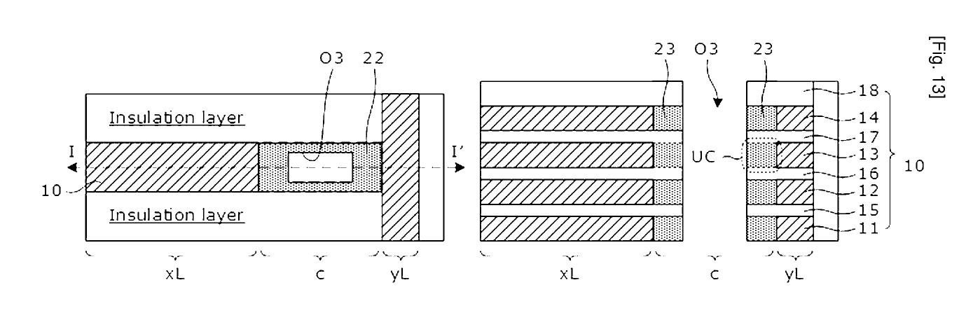

FIGS. 11 through 16 are diagrams illustrating a method of fabricating switching elements according to exemplary embodiments of the present invention. In each of FIGS. 11 through 16, a left diagram is a plan view, and a right diagram is a cross-sectional view taken along a dotted line I-I′ of the plan view.

Referring to FIG. 11, first layers 11, 12, 13, and 14 and second layers 15, 16, 17, and 18 interposed therebetween may be sequentially and alternately formed on a substrate (not shown) and patterned to form a multilayered layer structure 10. As described above with reference to FIG. 7, the layer structure 10 may include x-lines xL and y-lines yL, and the x-lines xL may be connected to the y-lines yL.

According to the present embodiment, a third opening O3 penetrating vertically the layer structure 10 may be formed in a region ‘c’ interposed between the x-line xL and the y-line yL. As shown, the third opening O3 may be formed apart from a sidewall of the x-line xL by a predetermined distance (hereinafter, first distance d1). Distances between the third opening O3 and opposing sidewalls of the x-lines xL may be substantially equal with each other, but it is also possible that the distances are variously changed within such a range as to satisfy a condition of d1<d3<d2 that will be described later. The third opening O3 may be formed as a circular or elliptical type. In this case, the first distance d1 may be a distance between the sidewall of the x-line xL and the sidewall of the third opening O3 positioned most adjacent thereto.

The third opening O3 may be formed to expose a top surface of the substrate. However, according to other embodiments, a predetermined insulating layer, for example, an isolation layer, may be formed in the substrate under the third opening O3. Also, when an upper switching line 920 is formed before the layer structure 10 according to some embodiments, the third opening O3 may expose a top surface of the upper switching line 920.

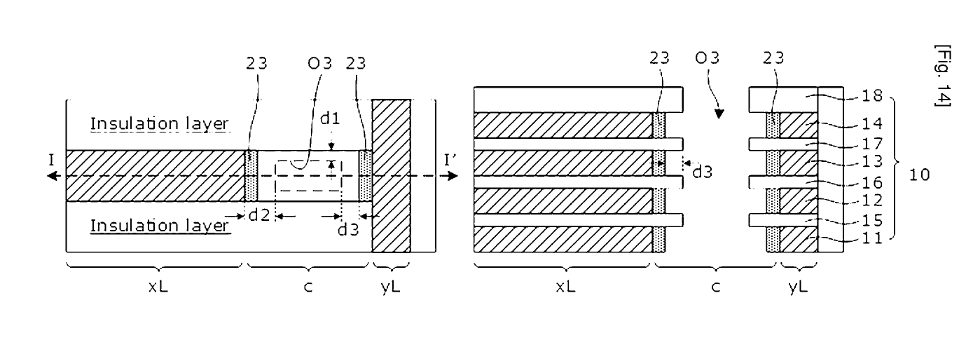

Referring to FIG. 12, sidewalls of the first layers 11 to 14 exposed by the third opening O3 may be recessed, thereby forming undercut regions UC between the second layers 15 to 18. The formation of the undercut regions UC may include selectively etching the first layers 11 to 14 using an isotropic etching process while minimizing the etching of the second layers 15 to 18. Also, the formation of the undercut regions UC may be performed using an etch recipe capable of selectively etching only the first layers 11 to 14 so as to prevent an unnecessary expansion of the undercut regions UC. In this case, the first layers 11 to 14 may be etched to a depth that corresponds to a second distance d2 greater than the first distance d1.

Thereafter, a first semiconductor layer 22 may be formed to fill the undercut regions UC. The first semiconductor layer 22 may wholly or partially fill the third opening O3 to directly contact recessed sidewalls of the first layers 11 to 14. The first semiconductor layer 22 may be a single crystalline silicon layer formed by means of an epitaxial process using the exposed substrate as a seed layer. According to other exemplary embodiments, the first semiconductor layer 22 may be a single crystalline silicon layer, an amorphous silicon (a-Si) layer, or a polycrystalline silicon (poly-Si) layer, which is formed using a chemical vapor deposition (CVD) technique. In addition, the first semiconductor layer 22 may be formed of one of III-V group compound semiconductors and organic semiconductor materials or a carbon nanostructure.

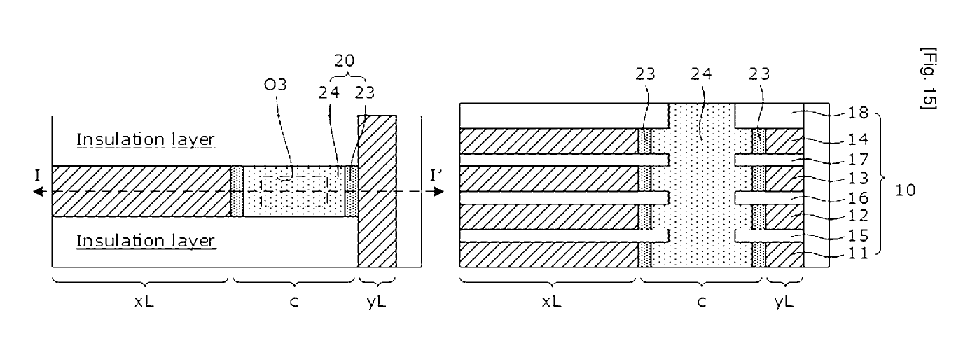

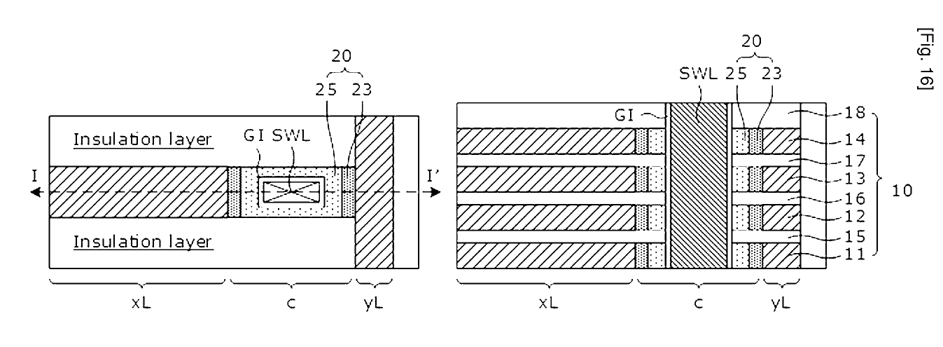

Referring to FIGS. 13 and 14, the first semiconductor layer 22 may be etched, thereby forming first semiconductor patterns 23 in the undercut regions UC.

According to some embodiments, as shown in FIG. 13, the formation of the first semiconductor patterns 23 may include etching the first semiconductor layer 22 by means of an anisotropic etching process using the uppermost second layer 18 or an additional mask pattern as an etch mask to remove the first semiconductor layer 22 from the third opening O3. In this case, the first semiconductor layer 22 may be vertically separated to form the first semiconductor patterns 23 filling the undercut regions UC, respectively. Thereafter, as shown in FIG. 14, the first semiconductor patterns 23 may be etched using an isotropic etching process, thereby recessing sidewalls of the first semiconductor patterns 23 from the third opening O3. In this case, the first semiconductor patterns 23 may be etched to a depth d3 that is greater than the first distance d1 and smaller than the second distance d2. As a result, the first semiconductor patterns 23 may be horizontally separated and locally formed on both sides of the third opening O3.

Referring to FIG. 15, a second semiconductor layer 24 may be formed to fill the undercut regions UC. The second semiconductor layer 24 may have a different conductivity type from the first semiconductor layer 22. The second semiconductor layer 22 may be formed using the substrate or the first semiconductor patterns 23 as a seed layer. Alternatively, the second semiconductor layer 22 may be formed using a CVD process. The second semiconductor layer 24 may be formed of a semiconductor material that is the same as or different from the first semiconductor layer 22.

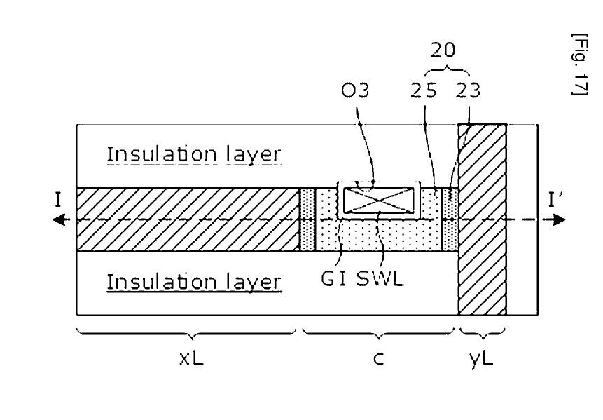

Referring to FIG. 16, the second semiconductor layer 24 may be etched by means of an anisotropic etching process using the uppermost second layer 18 or an additional mask pattern as an etch mask, thereby removing the second semiconductor layer 24 from the third opening O3. In this case, the second semiconductor layer 24 may be vertically separated to form second semiconductor patterns 25 filling the undercut regions UC, respectively. In order to enable vertical separation of the second semiconductor layer 24, isotropically or anisotropically etching the second semiconductor layer 24 may be further performed.

Afterwards, a switching gate insulating layer GI may be formed to cover sidewalls of the second semiconductor patterns 25, and switching lines SWL may be formed to fill the third opening O3 in which the switching gate insulating layer GI is formed. As a result, the switching lines SWL may be formed opposite the sidewalls of the second semiconductor patterns 25. The switching gate insulating layer GI may be formed using a thermal oxidation process or a CVD process and conformably cover an inner wall of the third opening O3. The switching lines SWL may be formed to fill the third opening O3 having the switching gate insulating layer GI and used as a gate electrode disposed opposite the semiconductor patterns 25.

Meanwhile, since the first and second semiconductor patterns 23 and 25 have different conductivity types, the first and semiconductor patterns 23 and 25 may be respectively used as source and drain electrodes and a channel region of a MOS transistor. That is, when the second semiconductor pattern 25 is inverted in response to a voltage applied to the switching line SWL, the x-line xL may be electrically connected to the y-line yL.

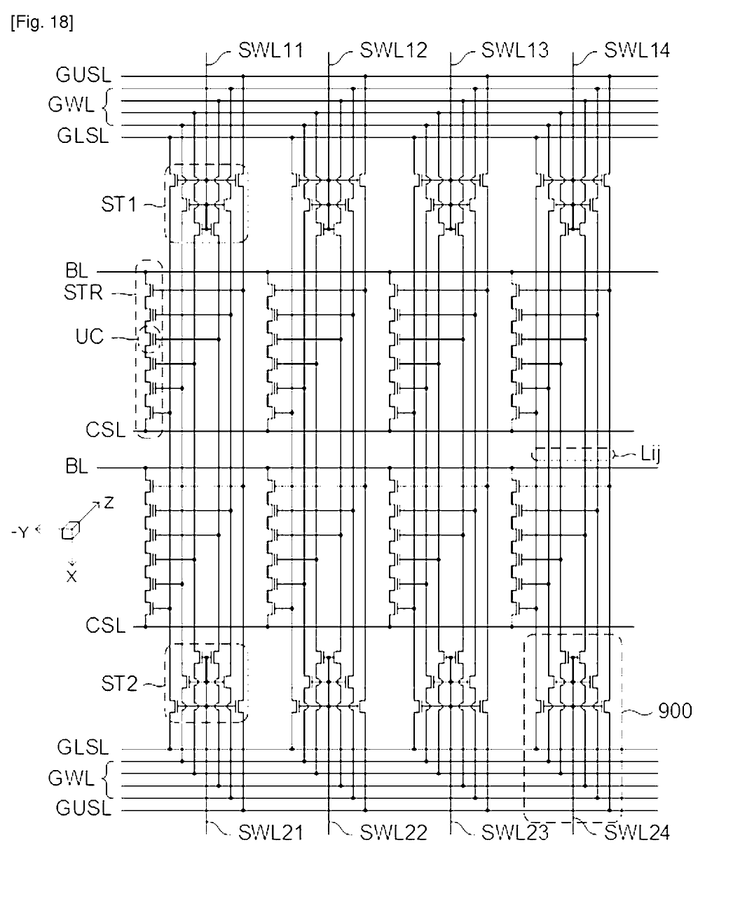

According to modified exemplary embodiments of the present invention, as shown in FIG. 17, the third opening O3 may be offset from the center of the x-line xL. In this case, a relationship among the first through third distances d1, d2, and d3 or the size of the third opening O3 may be selected within such a range as to satisfy the above-described condition of d1<d3<d2. Furthermore, the third opening O3 may be formed to an increased area to facilitate formation of the first semiconductor layer 22. For example, the third opening O3 may be formed in the shape of a line that has a greater width than the width of the x-line xL and crosses a plurality of x-lines xL. In this case, removing the first and second semiconductor layers 22 and 24 between the x-lines xL may be further performed. According to another modified exemplary embodiment, in order to minimize the width of the x-line Lij and secure a spacing margin between the switching lines SWL, the switching lines SWL may be disposed to be zigzag (that is, at positions corresponding to apexes of a letter ‘W’). For instance, the switching lines SWL may constitute at least two groups disposed different distances from the y-line.

Meanwhile, the above-described method of forming patterns using the undercut regions UC may be employed to form a controllable rectifying element, such as a bipolar transistor or a diode as the switching element, instead of a MOS transistor.

FIGS. 18 and 19 are a circuit diagram and perspective view of a memory semiconductor device according to exemplary embodiments of the present invention. For brevity, a description of the same technical features as in the embodiments described with reference to FIGS. 1 through 10 will be omitted.

Referring to FIGS. 18 and 19, the semiconductor device according to the present embodiments may include a local line structure including a plurality of local lines Lij, global line structures disposed on both sides of the local line structure, and switching structures 900 disposed between the local line structure and the global line structures. The local line structure, the global line structure, and the switching structures 900 may respectively correspond to the local line structure, the first and second global line structures, and the first and second switching elements ST1 and ST2, which are described above with reference to FIGS. 1 through 10. In this case, the global line structures may include global upper selection lines GUSL, global lower selection lines GLSL, and global word lines GWL interposed therebetween. The global lower selection lines GLSL may include lowermost global lines GL11 and GL21, the global upper selection lines GUSL may include uppermost global lines GL14 and GL24, and the global word lines GWL may include global lines G12, G13, G22, and G23 interposed therebetween. According to other embodiments, the lowermost or uppermost global lines may be not separated from each other and connected with each other to be a plate shape. In this case, bottom surfaces of the switching lines SWL may be leveled higher than top surfaces of the lowermost global lines GL11.

As shown in FIGS. 18 and 19, vertical semiconductor patterns SP having z-directional major axes may be disposed between the global lines Lij, and bit lines BL may be disposed across the global lines Lij on the vertical semiconductor patterns SP. The bit lines BL may be connected to the vertical semiconductor patterns SP through bit line plugs (not shown).

A data storage structure may be interposed between the vertical semiconductor pattern SP and the x-line Lij. The data storage structure may include a charge storage layer, a phase change layer, and a magnetoresistance (MR) element, and technical features disclosed in known documents related thereto may be incorporated in the present invention. When a charge storage layer is used as the data storage structure, a semiconductor device including the charge storage layer may be employed as a 3D NAND FLASH memory device. However, the technical scope of the present invention is not limited to such FLASH memory device.

A common source line CSL may be disposed under the vertical semiconductor patterns SP to connect the vertical semiconductor patterns SP. The common source line CSL may be an impurity region formed in the substrate. The vertical semiconductor pattern SP may include at least one region of a different conductivity type from the common source line CSL.

The electrical state of the vertical semiconductor patterns SP may be controlled by the x-lines Lij disposed adjacent thereto. Thus, a current path (hereinafter, vertical path) passing through the bit line BL, the semiconductor pattern SP, and the common source region CSL may be controlled in response to voltages applied to the x-lines Lij.

Meanwhile, since a plurality of vertical semiconductor patterns SP are connected to each of the bit lines BL, when a single bit line BL is selected, a plurality of vertical semiconductor patterns SP having the same x-coordinate and different y-coordinates may be selected. Here, one of the vertical semiconductor patterns connected by the bit line BL can be uniquely selected by selecting one of uppermost local lines. That is, by selecting one bit line BL and one uppermost local line L4j, a vertical path passing through one semiconductor pattern SP can be determined or specified. Similarly, an electrical connection between the one vertical semiconductor pattern SP and the common source line CSL may be controlled by the lowermost local line L1j.

However, when memory cells are arranged three-dimensionally, selection of a vertical path corresponds to a process of selecting one out of a plurality of cell strings STR that connect the bit line BL and the common source line CSL. In other words, selecting a memory cell out of a selected cell string requires an additional process of selecting a z-coordinate of the memory cell (hereinafter, a cell selection operation). The cell selection operation may be enabled by controlling voltages applied to the x-lines Lij. The cell selection operation may be attained using a known method of operating a NAND flash memory or a variation thereof except that the cell string is vertical.

Meanwhile, the vertical path selection operation and the cell selection operation may be variously varied according to the type of a memory cell and the structure of a cell array. Hereinafter, variations of the vertical path selection operation and the cell selection operation will be exemplarily described in more detail.

FIGS. 20 and 21 are a circuit diagram and perspective view of a memory semiconductor device according to other embodiments of the present invention.

According to the present embodiment, vertical semiconductor patterns SP are respectively formed on a plurality of connection nodes CI, which are spaced apart from one another to constitute a node string. Bit lines BL may run across x-lines Lij and connect the connection nodes CI. In the present embodiment, a bit number per area may be increased as compared with the embodiments described above with reference to FIGS. 18 and 19, as will be described later in more detail with reference to FIGS. 46 to 53. Meanwhile, the arrangements and directions of bit lines BL and source lines SL may be variously varied as will be described in the following embodiments and combinations thereof.

[Methods of Selectively Forming a Current Path I: Blocking a Sneak Path]

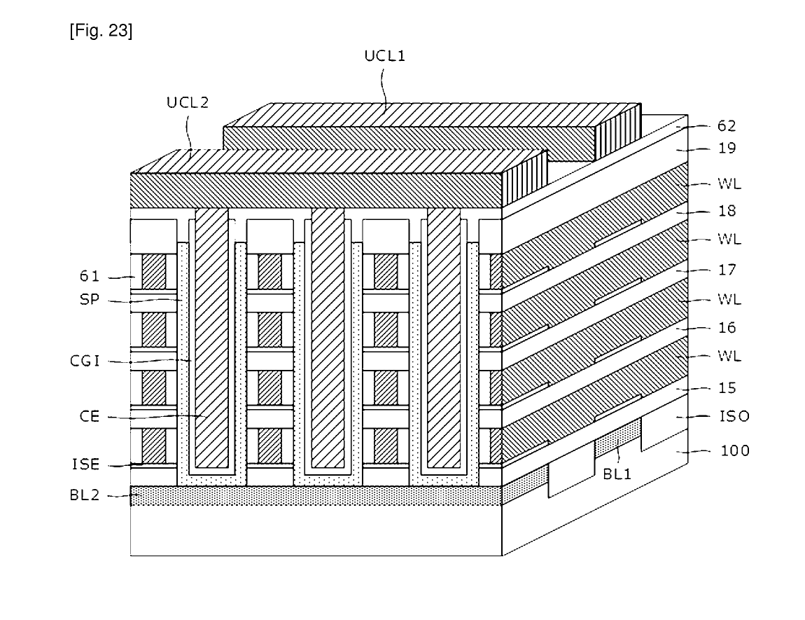

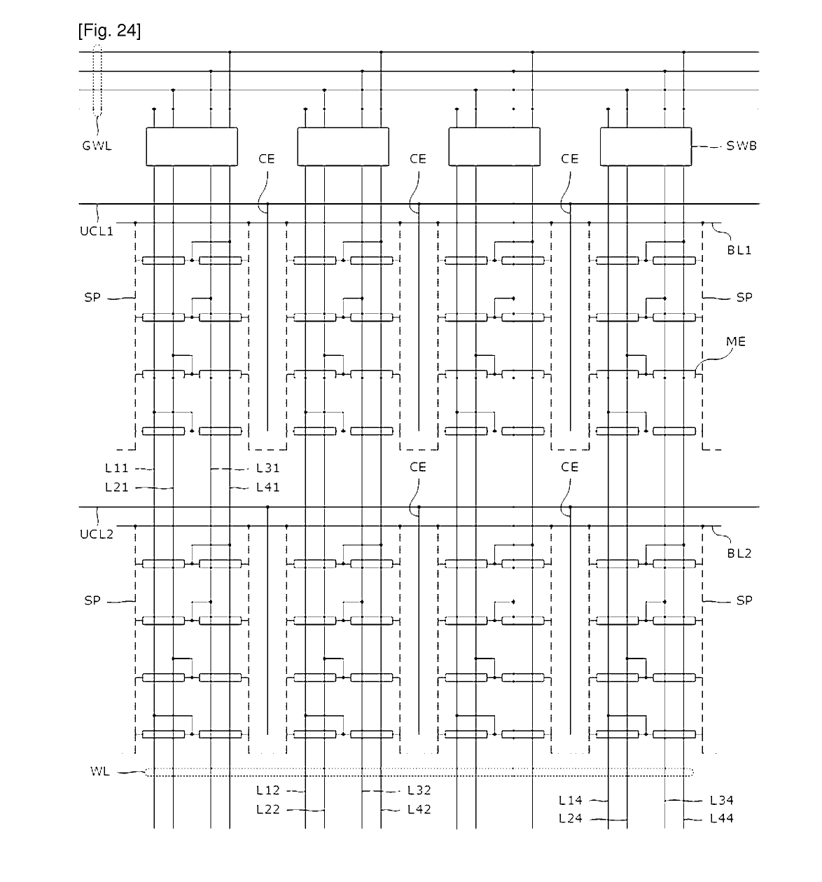

FIGS. 22 and 23 are respectively a circuit diagram and perspective view illustrating a structure configured to prevent a sneak path, according to exemplary embodiments of the present invention. FIGS. 24 to 36 are circuit diagrams and perspective views illustrating structures according to modified embodiments of the present invention. In the modified embodiments, the same technical features as in the afore-described embodiments may not be explained hereinbelow for brevity.

Referring to FIGS. 22 and 23, a plurality of word line structures are disposed on a substrate 100. Each of the word line structures may include a plurality of word lines WLs that are stacked sequentially. Also, each of the word line structures may be connected to global word lines GWL through a specific switching block SWB. According to one embodiment, the word lines WLs, the switching block SWB, and the global lines GWLs may be respectively the x-lines Lij, the switching elements STs, and the global lines GLs according to one of the embodiments discussed with reference to FIGS. 1 through 21.

The word lines WL, which constitute a single one of the word line structure, may be electrically and vertically separated by interlayer dielectrics (ILDs) disposed therebetween, and an information storage element ISE may be disposed between an ILD and the word line WL. According to some embodiments of the present invention, the information storage element ISE may be one of variable resistance elements (e.g., phase-change material), magneto-resistive elements (e.g., magnetic tunnel junction) and charge storing layers (e.g., silicon nitride). According to some embodiments, the information storage elements ISE, which are selected by one word line WL, may be horizontally and electrically separated from each other. However, in the case that there is no necessity to separate the information storage elements ISE, the information storage elements ISEs may be formed continuously. For instance, in some phase-change RAM devices, data may be stored in a localized region of a separation-less phase change layer.

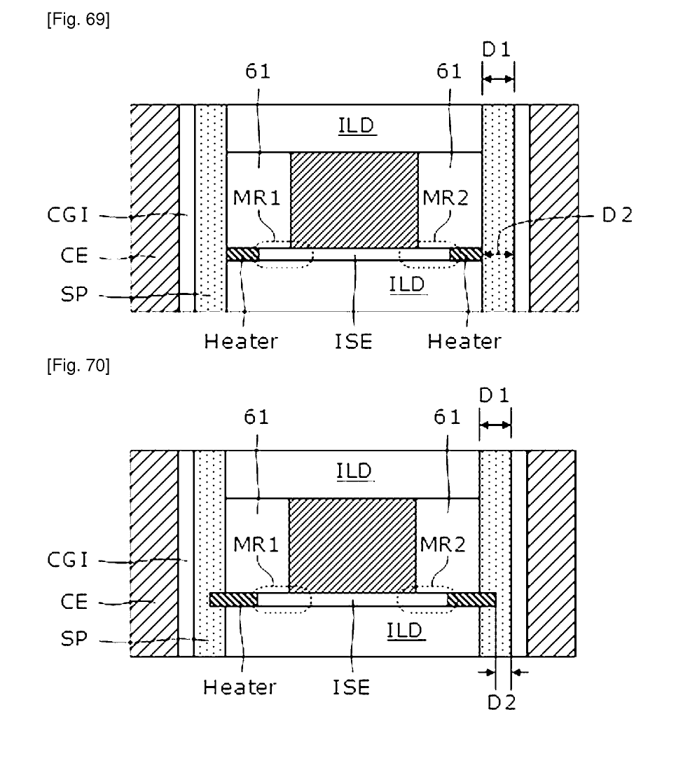

Semiconductor patterns SP, which are electrically connected to the information storage elements ISE, are disposed between the word line structures. The semiconductor patterns SP may have major axes vertical to a top surface of the substrate 100 and be formed to be spatially separated from each other. Each of the semiconductor patterns SP may be directly connected to the information storage element ISE. Alternatively, as shown in FIGS. 69 and 70, each of the semiconductor patterns SP may be connected to the information storage element IS through additional conductive material and may be connected in parallel to the plurality of information storage elements IS. Here, the semiconductor pattern SP may be separated from the word lines WLs, and for this end, a width of the word line WL is smaller than a space between laterally adjacent ones of the semiconductor patterns SP and an insulating pattern 61 may be disposed between the semiconductor pattern SP and the word line WL.

A process of forming the word line structures may include sequentially forming thin layers constituting the word line structures (e.g., the ILDs, layers for the information storage element, and layers for the word lines) and patterning the thin layers to form opened regions in which the semiconductor patterns SP will be located. In addition, in order to enable electrical insulation between the word line WL and the semiconductor pattern SP, the patterning process may be further followed by a lateral etching step of selectively recessing sidewalls of the word lines WLs or a lateral filling step of filling the recessed regions with an insulating layer. The insulating pattern 61 may be a resultant structure of the lateral filling step. Despite a difference in material, these steps may be performed using or modifying the fabrication method including a step of forming an undercut region, which is explained with reference to FIGS. 11 to 16.

According to other modified embodiments, a process of electrically insulating the information storage elements ISEs from one another may be further performed. For example, each of the steps of forming the layers for the information storage element may include patterning the layers for the information storage element in direction crossing the word lines. Alternatively, mask patterns, which have major axes vertical to a top surface of the substrate, may be formed between the word line structures. Thereafter, sidewalls of the layers for the information storage element may be selectively etched using the mask patterns as an etching mask. Here, the semiconductor patterns SP may be used as the etching mask for etching sidewalls of the layers for the information storage element.

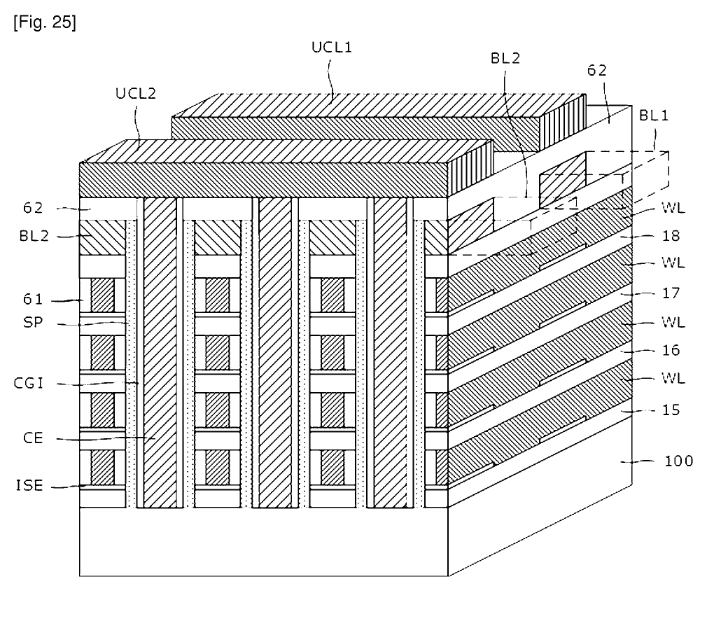

The semiconductor pattern SP may have a “U” shape with a closed upper or lower portion as shown in FIG. 23 or a cylindrical shape defining a gap region as shown in FIG. 25. However, as long as a MOS capacitor explained blow is effectively configured, the shape of the semiconductor pattern SP may be variously modified depending on a fabrication process. A detailed description on these modifications will be omitted in that these modifications can be easily achieved by those skilled in the art.

A plurality of upper control lines UCL1 and UCL2, which connect the semiconductor patterns SP and intersect the word lines WL, may be disposed over or below the word line structure. A plurality of control electrodes CE may be respectively inserted into gap regions of the semiconductor patterns SP and connected to the upper control lines UCL. A control gate insulating layer CGI may be interposed between the control electrode CE and the semiconductor pattern SP. Thus, the control electrode CE and the semiconductor pattern SP may constitute a MOS capacitor, and an electrical potential of the semiconductor pattern SP may be controlled by a voltage applied to the control electrode CE.

In order to realize the MOS capacitor, the semiconductor pattern SP may be formed of at least one selected from the group consisting of Group IV materials, Group III-V materials, organic semiconductor materials, and carbon nanostructures. Also, the semiconductor pattern SP may have a single crystalline structure, a polycrystalline structure, or an amorphous structure. For example, the semiconductor pattern SP may be formed of single-crystalline silicon, which is grown from the semiconductor substrate 100 using an epitaxial technique. Alternatively, according to other embodiments, the semiconductor pattern SP may be formed of polycrystalline or amorphous silicon using a CVD process. In order to enable an electrical insulation between the upper control line UCL and the semiconductor pattern SP, an upper insulating pattern 62 may be interposed therebetween.

One end portion of the semiconductor pattern SP may be connected to at least one bit line BL crossing the word lines WL. A rectifying element may be formed between the bit line BL and the semiconductor pattern SP. For instance, the semiconductor pattern SP may include impurity regions, which have different conductivity types to constitute a diode.

According to the present embodiment, the bit line BL may be formed to cross the word lines WL below the semiconductor pattern SP. The bit lines BL may be electrically insulated from one another so that they can be separately controlled. For example, the bit lines BL may be impurity regions having a different conductivity type from the substrate 100. In this case, an isolation layer ISO may be interposed between the bit lines BL in order to make an electrical insulation therebetween solid. According to other embodiments, the bit lines BL may include low-resistivity metal materials, such as tungsten, tantalum nitride, and silicide.

Meanwhile, one information storage element ISE may be connected to one word line WL and two semiconductor patterns SP disposed on both sides of the word line WL. In this case, since the respective semiconductor patterns SP are spatially separated from one another, each of the semiconductor patterns SP may constitute two current paths connected to the word line WL through one information storage element ISE. As a result, one information storage element ISE can store at least two bits. Specifically, if a mechanism using localized variations in physical properties of the information storage element ISE is used to store data in the information storage element ISE, each of the semiconductor patterns SP can be used as an electrode for causing a localized variation in the information storage element ISE, and thus, the above-described multi-bit cell can be realized.

For example, when the information storage element ISE is a phase-change layer, the semiconductor patterns SP or the additional conductive material interposed therebetween may be used as a heater electrode for locally heating an adjacent phase-change layer. In particular, according to this embodiment, since a contact area between the phase-change layer and the heater electrode depends on a deposited thickness of the phase-change layer, it is easier to realize a phase-change memory having a reduced power consumption characteristic, which is a main object of phase-change memory technology. In addition, according to exemplary embodiments of the present invention, the respective phase-change layers may be completely or partially surrounded by the word lines WL, the ILDs disposed therebetween, the insulating pattern 61, or the additional conductive material, and thus, technical problems related to a variation in the composition of the phase-change layer may be suppressed.

Meanwhile, according to some exemplary embodiments of the present invention, the information storage element ISE may be used to realize not a multi-bit cell but a single bit cell, depending on the structure of a cell array or the operation principle of the information storage element ISE. These exemplary embodiments will be described in more detail later.

Referring to FIGS. 24 and 25, according to this embodiment, the bit line BL may be disposed over the word line structure and connect one end portions of the semiconductor patterns SP across the word lines WL. The bit line BL may include at least one of silicon and a metal material. When the bit line BL is formed over the word line structure like this, technical restrictions related to temperature conditions of the bit line BL may be relaxed compared with the previous embodiment, and thus, the bit line BL may include a low-resistivity metal material. Also, according to the present embodiment, the semiconductor patterns SP may be formed to penetrate through the bit line BL, and additional layers (not shown) functioning as etch stop layers may be further formed between the semiconductor patterns SP and the substrate 100.

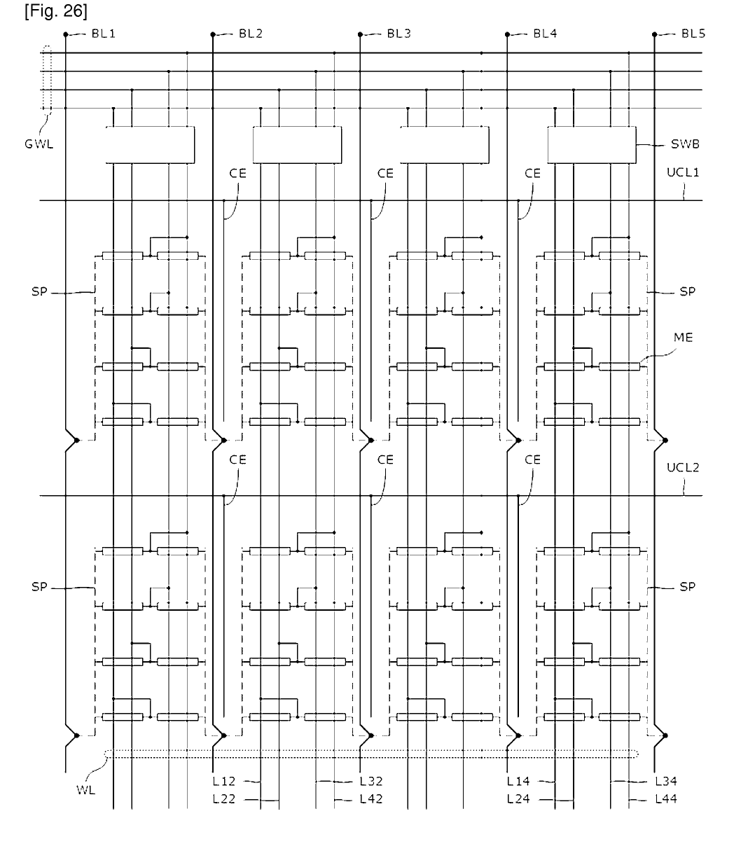

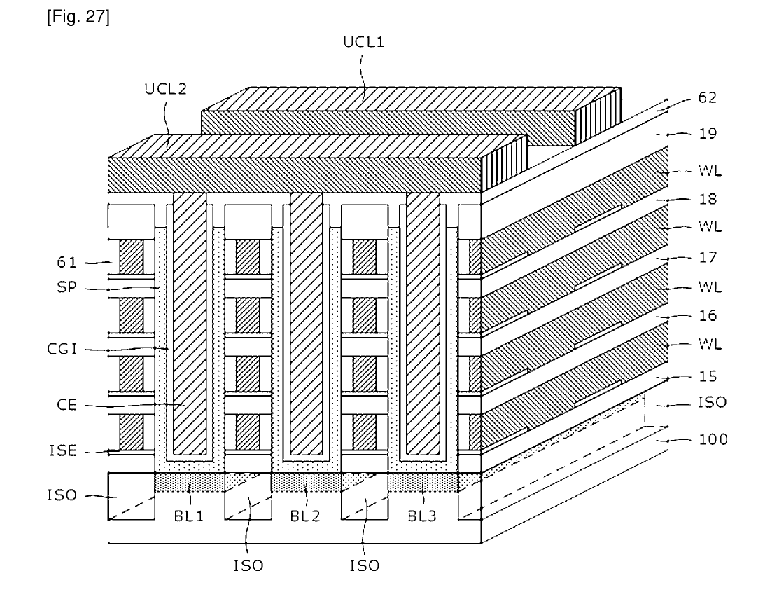

Referring to FIGS. 26 and 27, according to the present embodiment, the bit line BL may be formed under the semiconductor patterns SP and be formed along a direction parallel to the word lines WL. The bit lines BL may be formed using an ion implantation process using the word line structure as an ion mask. In this case, the bit lines BL may be self-aligned in the substrate 100 between the word lines WL. Also, the isolation layer ISO may be disposed under the word lines WL to enable an electrical isolation between the bit lines BL.

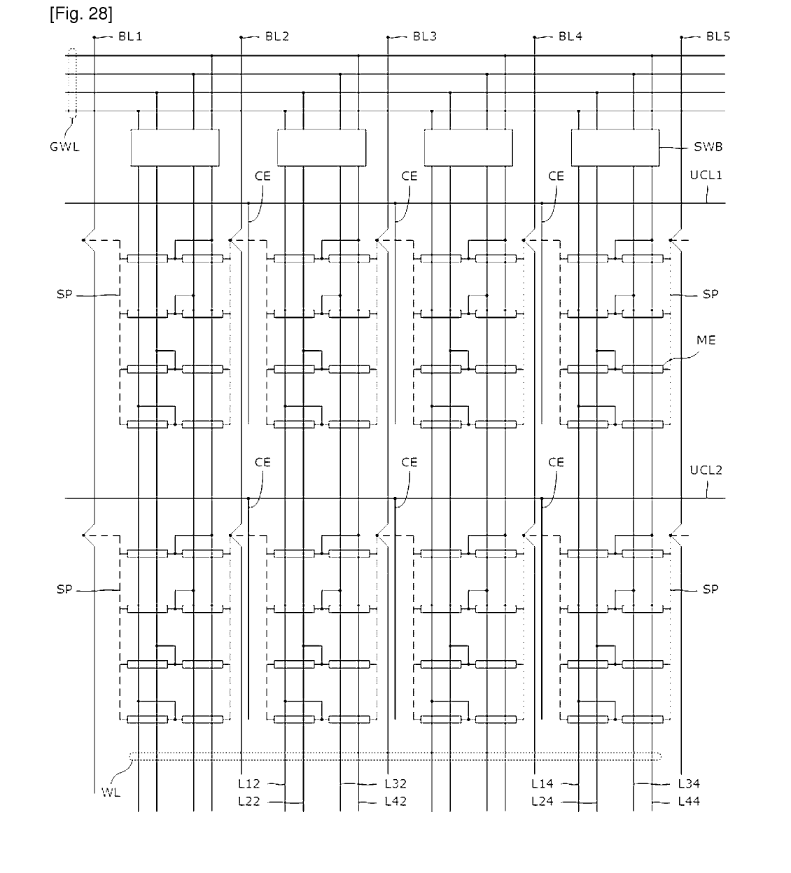

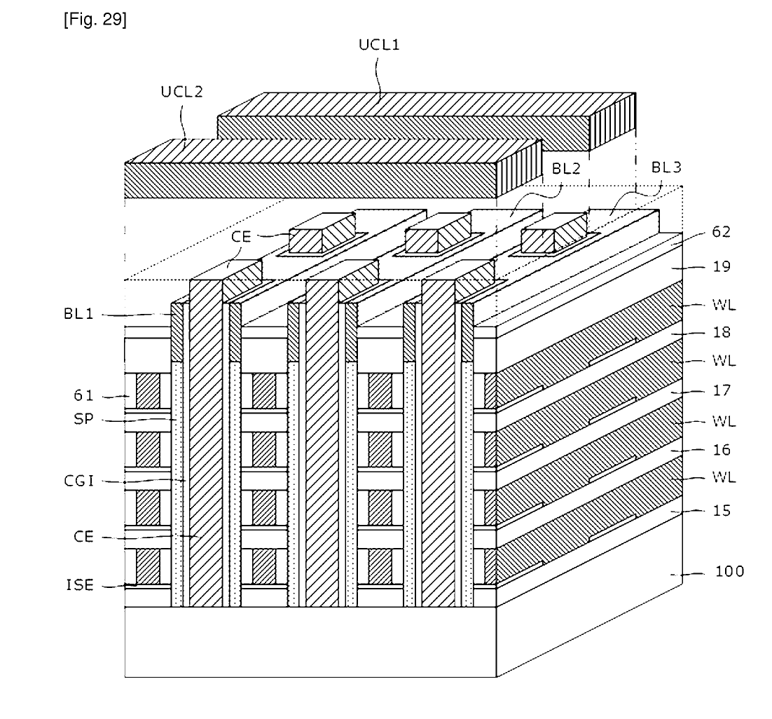

Referring to FIGS. 28 and 29, the bit line BL may be disposed over the word line structure and connect one end portions of the semiconductor patterns SP along a direction parallel to the word lines WL. A process of forming the bit line BL may include selectively recessing an upper region of the semiconductor pattern SP to form a gap region between the control electrode CE and the ILD thereabout, and filling the gap region with a conductive layer. In this case, an insulating layer may be further formed between the bit line BL and the control electrode CE to enhance an insulating characteristic therebetween.

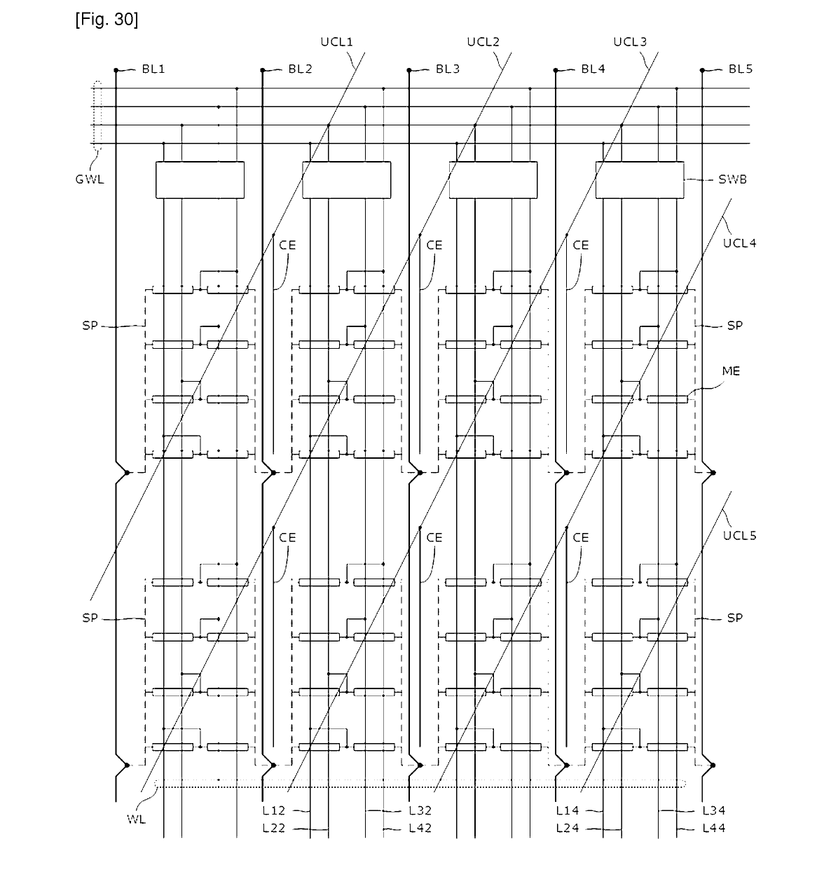

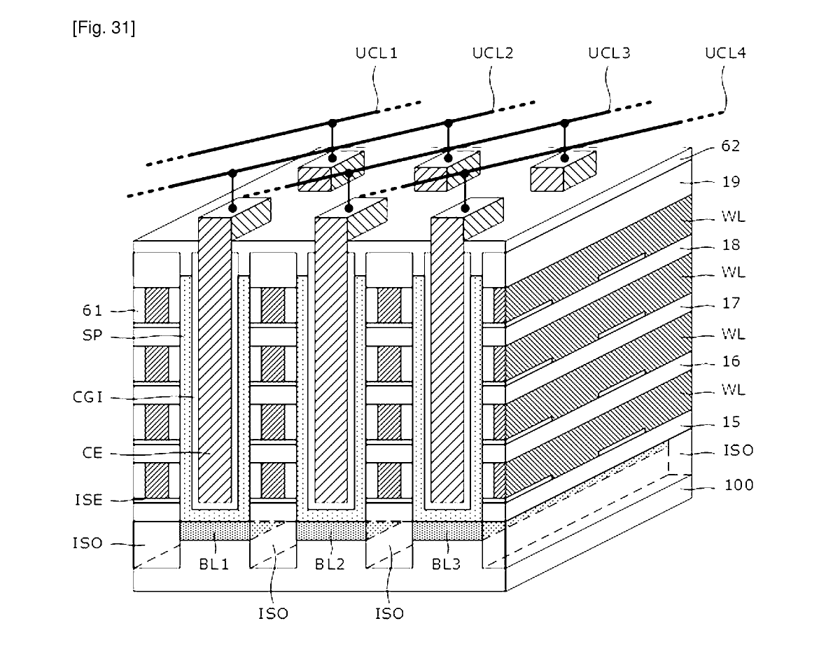

FIGS. 30 and 31 and FIGS. 32 and 33 illustrate modified embodiments of the embodiments described with reference to FIGS. 26 and 27 and FIGS. 28 and 29, respectively. According to these modified embodiments, each of upper control lines UCL may be disposed to connect semiconductor patterns SP, which are connected to different information storage elements ISE, out of the semiconductor patterns SP disposed on both sides of one word line. To do this, as shown in FIGS. 30 and 31, the upper control lines UCL may intersect the word line WL aslant to the word line WL.

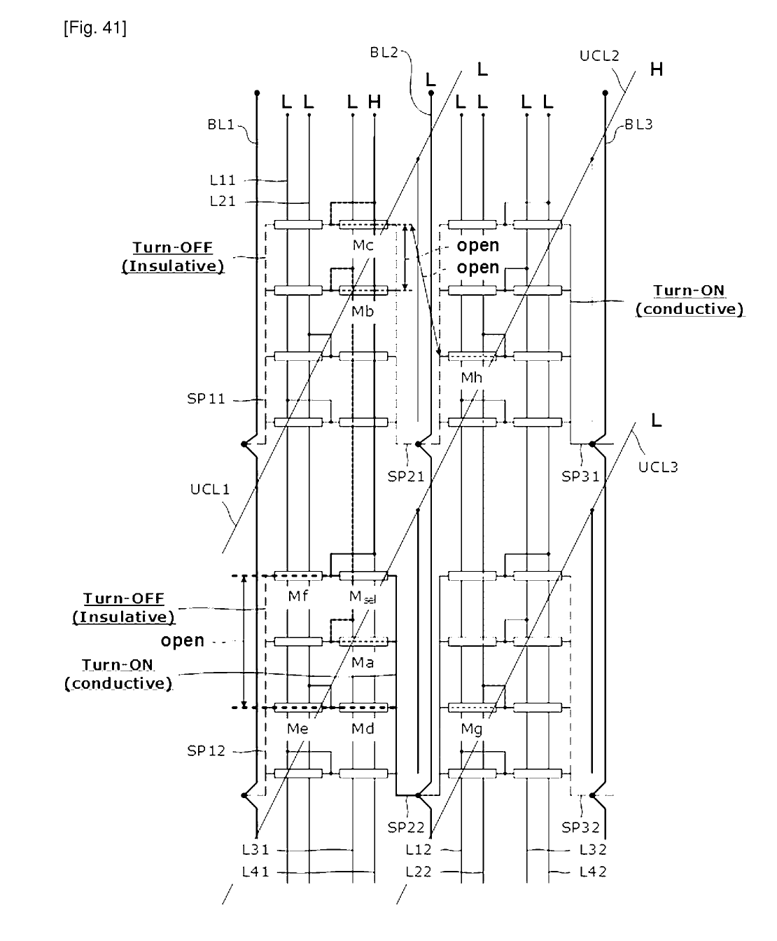

According to the afore-described embodiments, one upper control line UCL is electrically connected to two semiconductor patterns SP disposed on both sides of one information storage element ISE or one memory cell. Therefore, when one upper control line UCL is selected, the two semiconductor patterns SP disposed on both sides of the one memory cell may be selected at the same time. However, according to the present embodiment, when one upper control line UCL is selected, one of the two semiconductor patterns SP disposed on both sides of the one memory cell may be uniquely selected. The unique selection of the semiconductor pattern SP may be used to select one of two current paths provided by one information storage element ISE and the semiconductor patterns SP on both sides thereof. Using this, a multi-bit cell may be realized as described later with reference to FIG. 41.

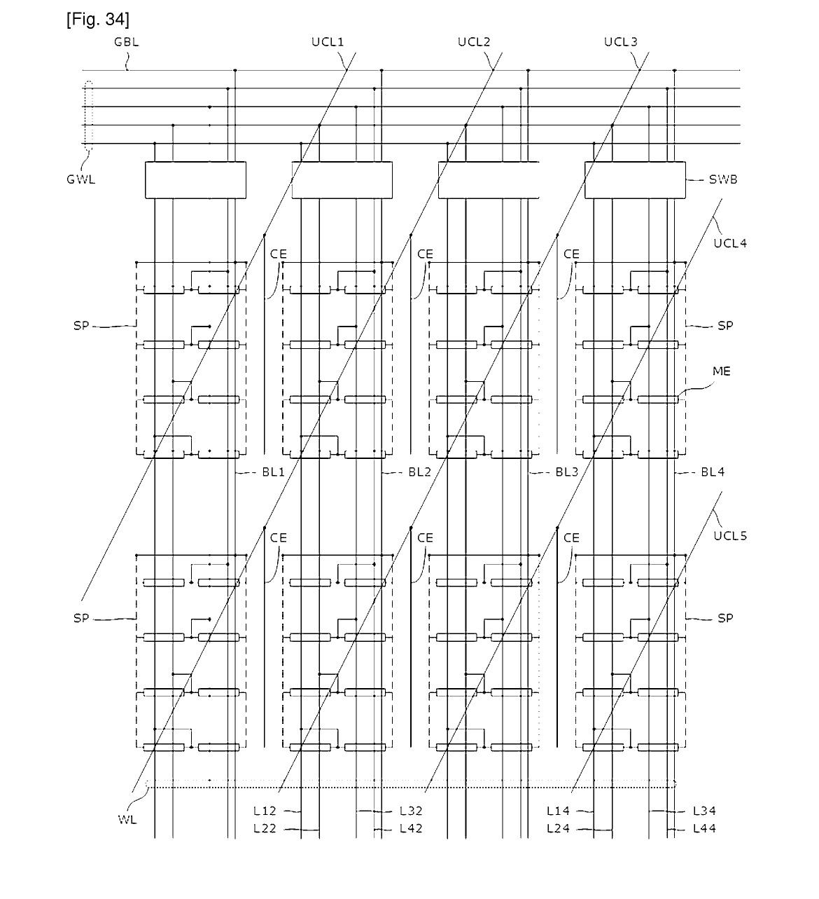

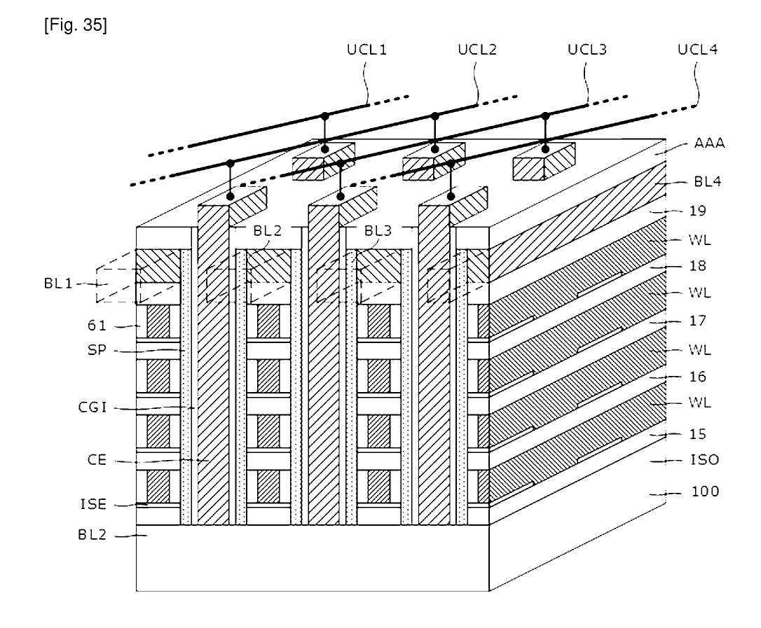

Referring to FIGS. 34 and 35, according to the present embodiment, each of the bit lines BL may have a major axis parallel to the word line WL and be disposed over the corresponding one of the word line structures. Thus, the semiconductor patterns SP disposed on both sides of one word line structure may be connected in common to one bit line BL. In this case, as shown in FIGS. 34 and 35, the upper control lines UCL may cross over the word line WL aslant to the word line WL as in the previous embodiment. However, according to modified embodiments, the upper control line UCL may be disposed to connect two semiconductor patterns SP disposed on both sides of one information storage element ISE or one memory cell as in the embodiments shown in FIGS. 28 and 29.

According to some embodiments, the bit line BL may be formed during formation of the word line structure. In this case, the bit line BL may be formed of a different material from the word line WL so that the bit line BL may not be recessed during a lateral etching step for forming the word line WL.

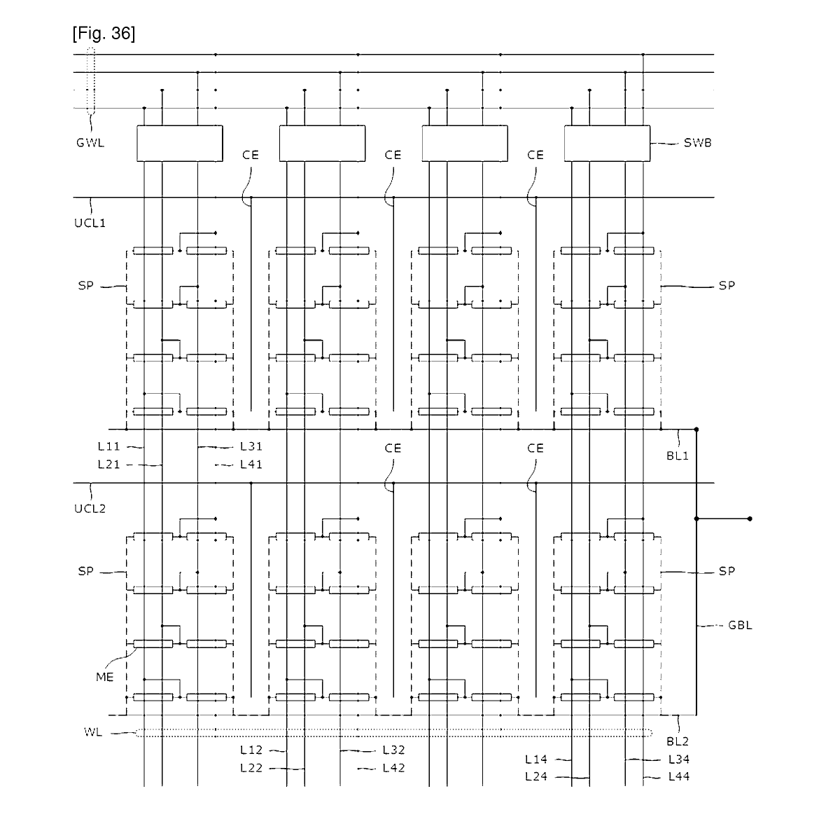

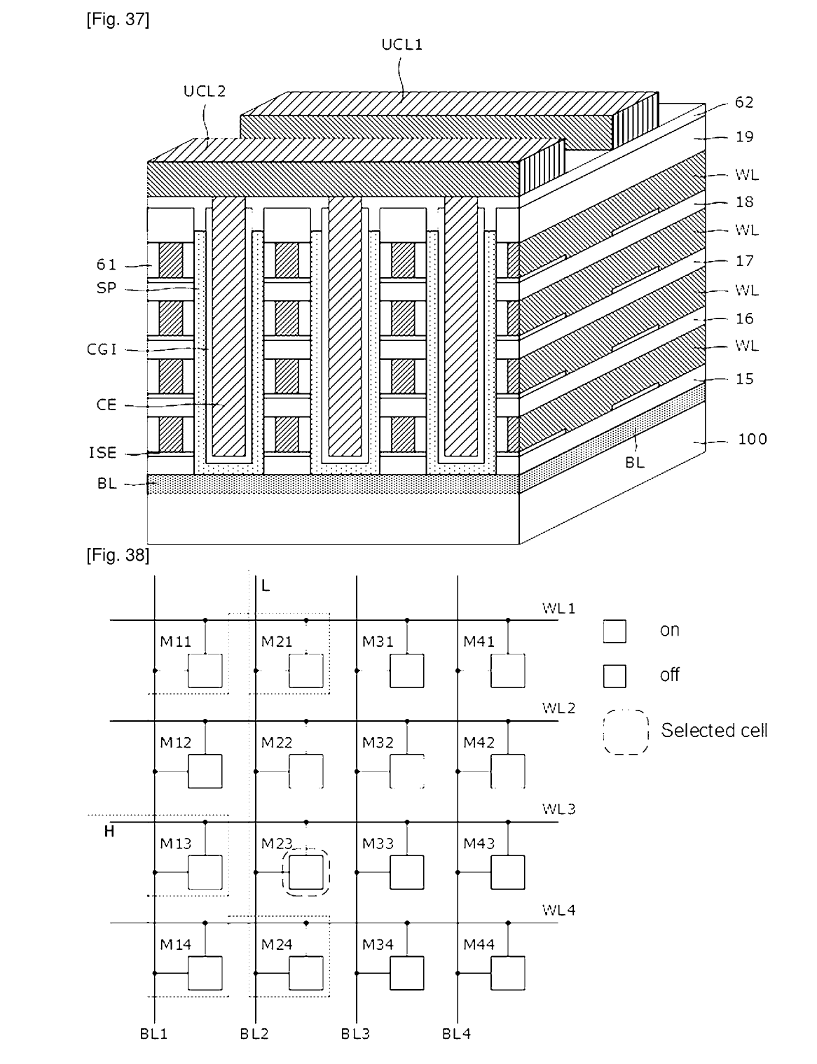

Referring to FIGS. 36 and 37, unlike in the previous embodiments in which the bit line BL connects the one-dimensionally arranged semiconductor patterns SP, according to the present embodiment, two-dimensionally connected semiconductor patterns SP may be connected in common to one bit line BL. For example, the bit line BL may be formed as a plate type under the word line structure as shown in FIG. 37.

Although not shown, according to other embodiments, the bit line BL may be formed over the word line structure and have openings in which the control electrodes CE can be disposed. Alternatively, the bit line BL may be disposed at an intermediate level between the word lines WL or in the middle of the word line structure. This may reduce technical difficulties caused by a distance difference between the bit line BL and the memory cells.

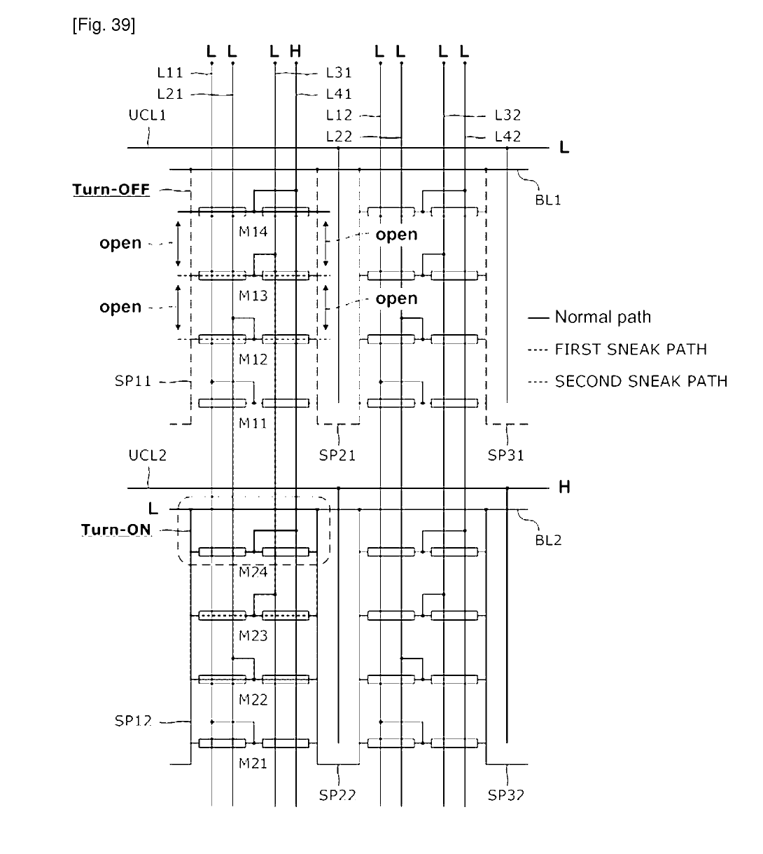

FIG. 38 is a diagram illustrating unintended current paths of a typical cross-point cell array structure, and FIGS. 39 through 41 are diagrams illustrating a method of preventing an unintended current path of a 3D semiconductor device according to exemplary embodiments. In FIGS. 38 through 41, a gray square denotes a turned-off memory cell, while a white square denotes a turned-on memory cell.

Referring to FIG. 38, an operation of writing or reading information in or from a selected memory cell (e.g., memory cell M23) may include selecting a bit line BL2 or word line WL3 connected to the selected memory cell M23. In this case, a normal current path may lead from the word line WL3 through the selected memory cell M23 to the bit line BL2. The amount of current flowing through the normal current path WL3-(M23)-BL2 may depend on the information stored in the selected memory cell M23. The amount of the current may be used to read information from a sensing circuit.

However, in the cross-point cell array structure, unintended paths connecting the selected lines BL2 and WL3, as illustrated with dotted lines, may be formed due to a plurality of turned-on cells connected to the selected lines BL2 and WL3. For example, see a path of WL3-M13-BL1-M11-WL1-M21-BL2 or a path of WL3-M13-BL1-M14-WL4-M24-BL2. These unintended paths may preclude reading information stored in the selected memory cell and hinder selective change of information stored in the selected memory cell. Thus, each of memory cells of a memory device including a typical cross-point cell array may include a transistor or diode functioning as a selection device for cutting off formation of unintended current paths. However, due to technical difficulties, such as a crystalline structure of a semiconductor material, a forming method, and a temperature restriction, it may be difficult to form the selection device in each of memory cells of a 3D memory semiconductor device. In order to put the 3D memory semiconductor device to practical use, the above-described technical difficulties should be overcome.

The technical difficulties can be solved by the embodiments of the present invention. FIG. 39 is a diagram illustrating a method of cutting off an unintended current path in the 3D semiconductor device described with reference to FIGS. 24 and 25. In FIG. 39, it is assumed that a memory cell M24 may be a turned-off selected memory cell, and a semiconductor pattern SP22 connected to the memory cell M24 is in a conductive or on state. The conductive state of the semiconductor pattern SP22 may be attained by applying a voltage higher than a threshold voltage to the corresponding upper control line UCL2. In this case, a normal current path may lead from the bit line BL2 through the semiconductor pattern SP22 being in the conductive state and the selected memory cell M24 to word line L41 (i.e., BL2-(SP22:conductive)-(M24)-L41), and the amount of current flowing through the normal current path may depend on the state of the selected memory cell M24.

Meanwhile, assuming that unselected cells M12, M13, M14, M23, and M22 are in an on state, a path of BL2-(SP22:conductive)-M23-L31-M13-(SP11/SP21)-M14-L41 and a path of BL2-(SP22:conductive)-M22-L21-M12-(SP11/SP21)-M14-L41 may be considered as unintended paths. However, in order to complete these sneak paths, semiconductor patterns SP11 and SP21 should be in a conductive state (or inversion state). That is, as shown in FIG. 39, if a voltage (e.g., ground voltage) lower than the threshold voltage is applied to the unselected upper control line UCL1, the semiconductor patterns SP11 and SP21 are in a nonconductive or off state, and therefore, a condition for completing a sneak path cannot be satisfied. In other words, the selected bit line BL2 cannot be electrically connected to the selected word line L41 by these unintended paths. Thus, in the 3D memory device according to the present embodiment, selective access to a target memory cell may be enabled without generating any sneak path.

Meanwhile, according to the present embodiment, a pair of semiconductor patterns (e.g., SP12 and SP22) disposed on both sides of a single word line structure may be connected to the same bit line BL2 and controlled by the same upper control line UCL2. Thus, although the pair of semiconductor patterns SP12 and SP22 are spatially separated from each other, they may be in a substantially equipotential state. As a result, the present embodiments may preclude realizing a multi-bit cell based on the above-described current-path separation. However, since there are various methods for realizing a multi-bit cell based not on the above-described current-path separation, it is obvious that the present embodiments are not incompatible with the formation of the multi-bit cell. For example, if the memory cells have non-symmetrical characteristics in terms of the thicknesses of thin layers, an area of contact with semiconductor patterns, and an interval between a word line and the semiconductor patterns, the non-symmetrical characteristics may be used to realize a multi-bit cell even in the above-described embodiment.

Meanwhile, even in the embodiments described with reference to FIGS. 22 and 23 and FIGS. 36 and 37, the above-described method may be used to prevent a sneak path.

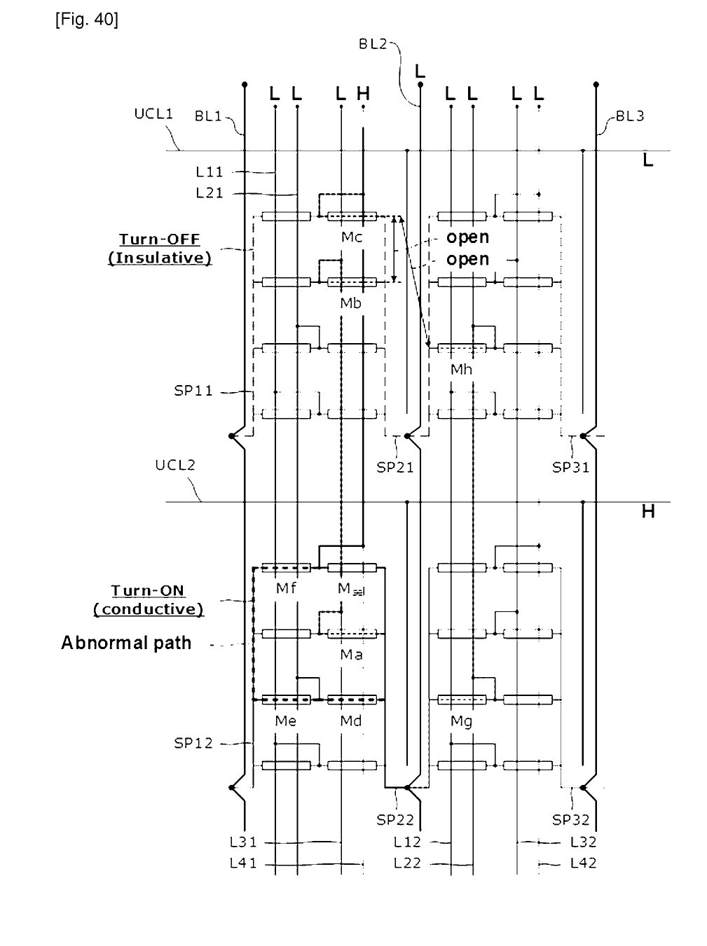

FIG. 40 is a diagram illustrating a method of cutting off an unintended current path in the embodiments described with reference to FIGS. 28 and 29. In FIG. 40, it is assumed that a memory cell Msel is a selected memory cell in an off state, and a semiconductor pattern SP22 connected to the memory cell Msel is in a conductive state. In this case, like in the previous embodiment, a normal current path may be BL2-(SP22:conductive)-(M24)-L41. In this case, even if unselected cells Ma, Mb, Mc, Mg, and Mh are in an on state, since the semiconductor pattern SP21 is in an off state as described above in the previous embodiment, a path of BL2-(SP22:conductive)-Ma-L31-Mb-(SP21)-Mc-L41 and a path of BL2-(SP22:conductive)-Mg-L22-Mh-(SP21)-Mc-L41 are not completed.

However, when other unselected cells Md and Me are in an on state, since the semiconductor pattern SP12 is in a conductive state, an abnormal path, such as a path of BL2-SP22-Md-Me-(SP12)-Mf-L41, may be completed. As a result, in the present embodiment, it may be difficult to realize a multi-bit cell using the separation of current-path. However, it is obvious that the present embodiments are not incompatible with a realization of the multi-bit cell when modified methods, for example, methods of controlling on-current characteristics of memory cells Mf and Msel, are applied. Furthermore, in the case that one bit is stored in one information storage element as in the previous embodiments (or the memory cells Mf and Msel store the same information), it is obvious that the method according to the present embodiments may effectively prevent the sneak path of the 3D semiconductor device.

FIG. 41 is a diagram illustrating a method of cutting off an unintended current path in the embodiments described with reference to FIGS. 30 and 31. According to the present embodiment, each of the upper control lines may be disposed to connect semi-conductor patterns (e.g., SP12 and SP22), which are connected to different information storage elements, out of semiconductor patterns (e.g., SP11, SP12, SP21, and SP22) disposed on both sides of one word line. In this case, as shown in FIG. 40, abnormal paths passing through unselected memory cells Mg and Mg may not be completed like in the previous embodiment.

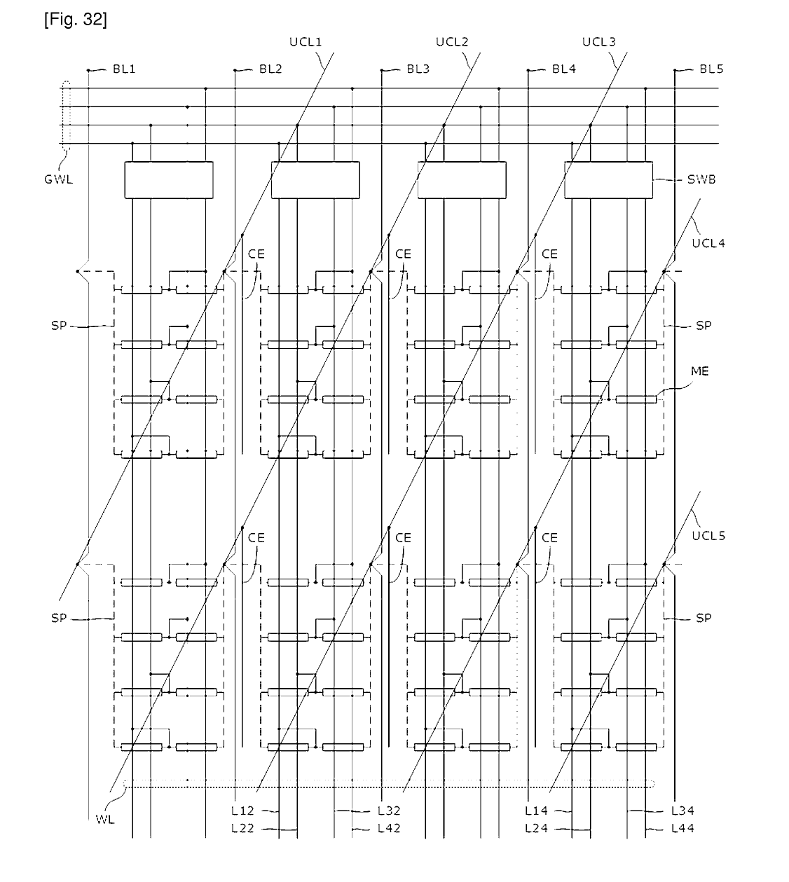

Furthermore, according to the present embodiment, when one upper control line (e.g., UCL2) is selected, one semiconductor pattern (e.g., SP22) can be uniquely selected out of two semiconductor patterns disposed on both sides of one memory cell. Thus, the path of BL2-SP22-Md-Me-(SP12)-Mf-L41, which is described in the previous embodiment, can be also prevent. As a result, according to the present embodiment, two bits may be stored in one information storage element ISE. In this case, any sneak path may not be formed. Even in the embodiments described with reference to FIGS. 32 through 35, a multi-bit cell may be realized without causing a sneak path using the above-described method.

The above-described cell array structures and methods of cutting off a sneak path were provided to exemplarily describe the technical spirit of the present invention. However, the present invention is not limited thereto, and, although not described above, those skilled in the art may realize other embodiments of the present invention using combinations or modifications of the above-described embodiments.

### [Magnetic Memory Device]

The above-described embodiments or modifications thereof may be employed to prevent a sneak path in a 3D magnetic memory device. Specifically, a spin-torque transfer mechanism (STTM) may be employed to change information stored in a magnetic memory cell. Magnetic memories based on the STTM may have cell array structures according to the above-described embodiments or modifications thereof except that a magnetic element, such as a magnetic tunnel junction (MTJ), is used as an information storage element ISE.

Meanwhile, according to other embodiments of the present invention, a unit cell of a magnetic memory device may include an MTJ including a free layer and a reference layer as shown in FIG. 44. A magnetic polarization of the free layer may be changed due to magnetic fields generated by currents flowing through interconnection lines (e.g., a word line and a semiconductor pattern) that intersect each other. In this case, semiconductor patterns SP may be used to form an additional current path that does not pass through the MTJ but is disposed adjacent to the MTJ.

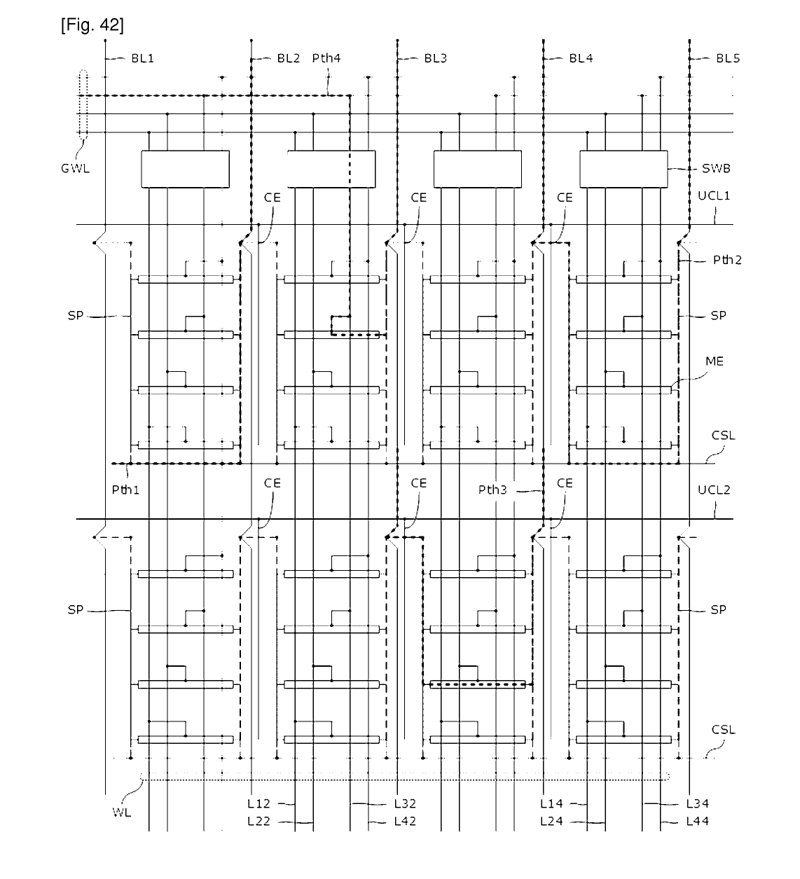

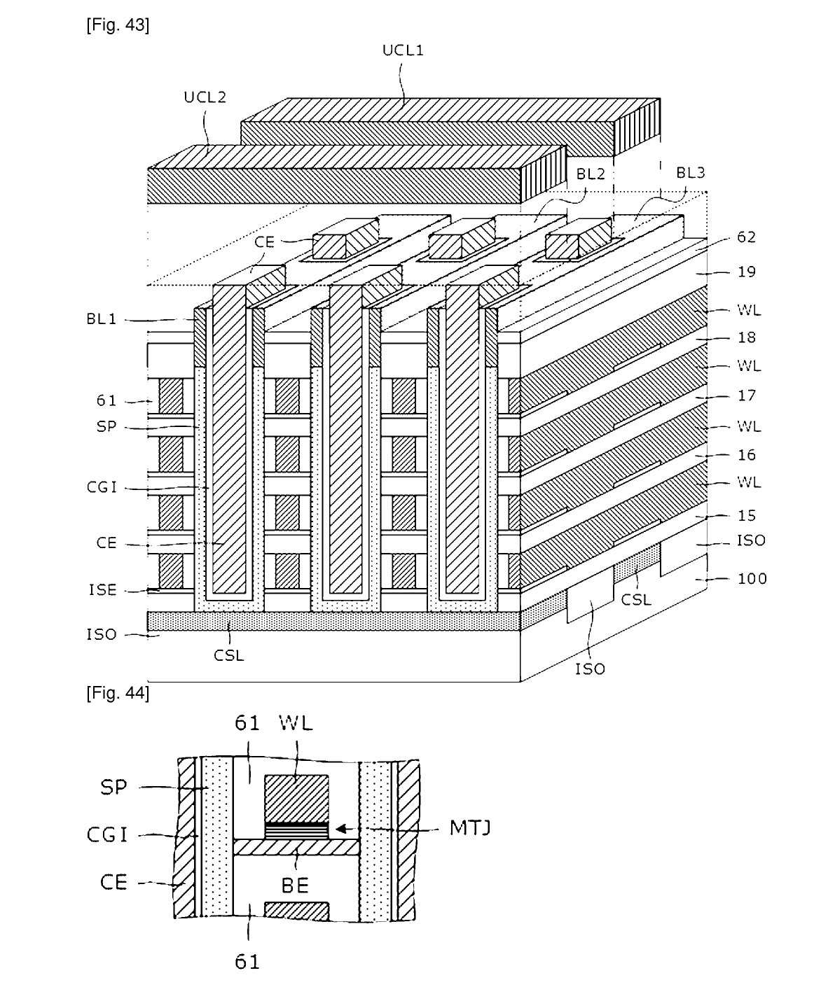

For example, as shown in FIGS. 42 and 43, the semiconductor pattern SP may be disposed such that one end portion and the other end portion of the semiconductor pattern SP are connected to a bit line 42 and a common source line CSL, respectively. Thus, a write current path Pth1 that does not pass through the MTJ may be formed. In this case, information stored in a selected magnetic memory cell (e.g., the magnetic polarization of the free layer) may be changed due to magnetic fields generated by write currents flowing through a selected word line WL and a selected semiconductor pattern SP. Since the word line WL and the semiconductor pattern SP have major axes that intersect each other, the magnetic fields generated by the currents flowing through the word line WL and the semiconductor pattern SP may have intersecting directions. As a result, information stored in the selected memory cell may be selectively changed. The selected semiconductor pattern SP may be turned on by the upper control line UCL intersecting the corresponding bit line BL so that a current path connected to the corresponding bit line may be formed without causing a sneak path.

A read operation may include sensing the amount of a read current that depends on the magnetic polarizations of the free layer and the reference layer and passes through the MTJ. As shown in FIG. 42, a path Pth4 of the read current may be configured to pass through the selected word line WL, a selected memory cell ME (i.e., MTJ), and the selected bit line BL. To do this, the MTJ may be connected to the semiconductor pattern SP through a bottom electrode BE disposed thereunder. In this case, since electrical connection of the bit line BL with the memory cell ME may be controlled by an on/off state of the corresponding semiconductor pattern SP or a voltage applied to the corresponding upper control line UCL, the read operation also may be performed under the condition of a unique current path passing through a selected memory cell without generating a sneak path.

Meanwhile, according to modified exemplary embodiments, the write current may have a path that sequentially passes through semiconductor patterns SP disposed on both sides of one memory cell ME. For example, like a second current path Pth2 of FIG. 42, a current path, which passes through a pair of semiconductor patterns SP connected to two adjacent bit lines BL and the common source line CSL, may be formed between the two adjacent bit lines BL. According to the present embodiments, since magnetic fields generated by the pair of semiconductor patterns SP are superposed and applied to a selected MTJ, the intensity of the magnetic fields applied to the selected MTJ may double that of magnetic fields in the embodiments that provide the current path Pth1.

According to other modified embodiments, the write current may have a path passing through the bottom electrode BE. For example, like a third current path Pth3 of FIG. 42, a current path passing through a pair of semiconductor patterns SP, which are connected to two adjacent bit lines BL, and the bottom electrode BE of the memory cell ME may be formed between the two adjacent bit lines BL. In this case, the write currents may flow in a direction intersecting major axes of the word line and the semiconductor pattern SP. Meanwhile, when the bottom electrode BE is formed of a semiconductor material, the current path may be formed only in a memory cell connected to a selected word line WL. That is, the current path may pass through a specific memory cell determined by the selected word line WL and the selected upper control line UCL.

Meanwhile, according to the embodiments related with a magnetic memory device, in order to inhibit magnetic fields generated due to the write or read currents from disturbing an unselected memory cell, a magnetic shielding layer may be disposed adjacent to the MTJ. At least one of the control gate insulating layer CGI, the insulating pattern 61, the ILDs, and the bottom electrode BE may include a material having a magnetic shielding characteristic.

### [Charge-Storage-Type Memory]

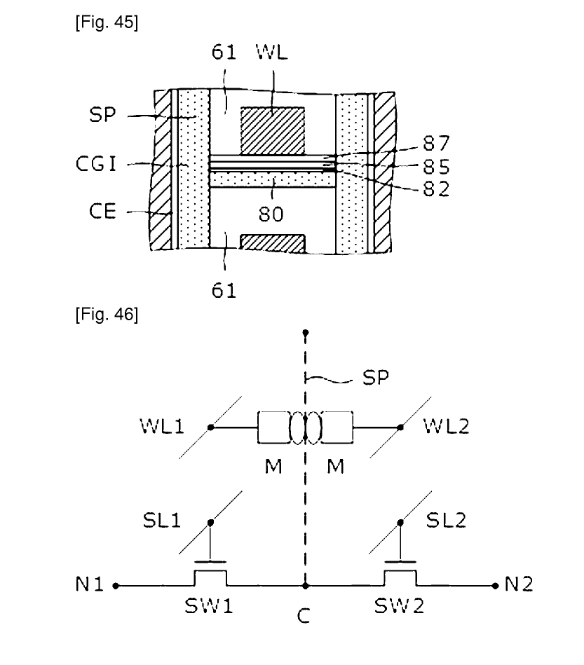

According to some exemplary embodiments, the information storage element ISE may include a charge storage layer. For example, as shown in FIG. 45, each of the memory cells may include a horizontal channel pattern 80, the word line WL, and a charge storage layer 85 interposed therebetween. A blocking insulating layer 87 may be disposed between the charge storage layer 85 and the word line WL, and a tunnel insulating layer 82 may be disposed between the charge storage layer 85 and the horizontal channel pattern 80. The horizontal channel pattern 80 may be formed of at least one of semiconductor materials, and the word line WL may be used as a gate electrode for controlling electrical potential of the horizontal channel pattern 80. Also, the horizontal channel pattern 80 may connect a pair of semiconductor patterns SP disposed on both sides of the word line structure. Thus, the semiconductor patterns SP may serve as source and drain electrodes of a transistor.

The cell array structures or according to the embodiments described with reference to FIGS. 22 through 42 or modifications thereof may be used to realize charge-storage-type 3D memory devices. For example, when the memory cells according to the embodiments described with reference to FIG. 42 constitute charge-storage-type transistors of FIG. 45, a resultant cell array may constitute a 3D NOR-type flash memory. That is, one of 3D NOR-type memory cells may be written or read through the path Pth3 of FIG. 42. However, technical features, such as directions of a bit line, a common source line, and upper control lines may be modified based on the embodiments described with reference to FIGS. 22 through 37. Furthermore, those skilled in the art may operate the above-described charge-storage-type 3D memory device using another method (e.g., NAND- or AND-type method) by changing voltage conditions based on the disclosures of known documents.

### [Selective Formation of a Current Path II]

According to at least one of the above-described embodiments, one semiconductor pattern SP may be connected in common to two adjacent word line structures having different y-coordinates. Specifically, the one semiconductor pattern SP may be used as a common current path for accessing to adjacent memory cells having different y-coordinates. Meanwhile, according to the following embodiments of the present invention, a current path passing through the semiconductor pattern SP may provide two current paths distinguished from each other by predetermined switching elements.

More specifically, referring to FIG. 46, a semiconductor device may include a first node N1, a second node N2, a connection node C disposed therebetween, and a semiconductor pattern SP having one end portion connected to the connection node C. Also, at least one first switching element SW1 may be disposed between the first node N1 and the connection node C to control electrical connection therebetween, and at least one second switching element SW2 may be disposed between the second node N2 and the connection node C to control electrical connection therebetween (hereinafter, an operation of controlling an electrical connection between nodes will be referred to as a node selection operation). Memory cells M including an information storage element and x-lines L1 and L2 connected to the information storage elements may be disposed around the semiconductor pattern SP. In this case, the semiconductor pattern SP may be selectively electrically connected to the first node N1 or the second node N2 by controlling on/off states of the switching elements SW1 and SW2. Here, the information storage element may include at least one of a charge storage layer, a phase-change layer, and an MR element.

Switching operations of the first and second switching elements SW1 and SW2 may be controlled by first and second selection lines SL1 and SL2 connected thereto, and first and second interconnection lines (not shown) may be connected to the first and second nodes N1 and N2, respectively. Here, at least one of the first and second interconnection lines may be disposed across the first and second selection lines SL1 and SL2. However, the direction of the first and second interconnection lines may vary with the type of memory cells and the structure of a cell array. Meanwhile, although the first and second switching elements SW1 and SW2 may be MOS transistors using the first and second selection lines SL1 and SL2 as gate electrodes, respectively, the present embodiments are not limited thereto. Also, the first and second selection lines SL1 and SL2 may have major axes penetrating through a plane defined by the first and second nodes N1 and N2 and the semiconductor pattern SP. The x-lines Lij described in the above-described embodiments with reference to FIGS. 1 through 21 may be used as at least one of the x-lines Lij and selection lines SL1 and SL2 of the present embodiment.

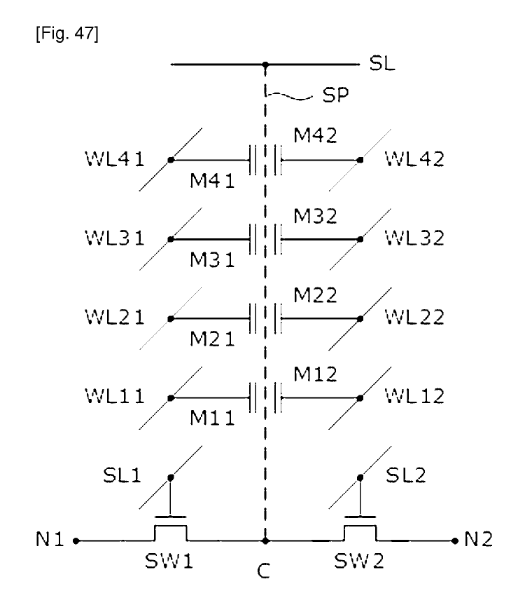

According to some exemplary embodiments, as shown in FIGS. 47 through 49, the x-lines Lij may be sequentially stacked to form a word lines structure and disposed opposite the semiconductor pattern SP. Thus, an electrical state of the semiconductor pattern SP may be controlled by a voltage applied to the x-lines Lij. For example, an electrical connection of a partial region of a semiconductor pattern, which is disposed adjacent to a predetermined x-line (e.g., L31), with the connection node C may be controlled by voltages applied to other x-lines (e.g., L21 and L11) disposed between the corresponding x-line L31 and the connection node C (hereinafter, an operation of controlling the electrical connection of the connection node C with a memory cell will be referred to as a cell selection operation).

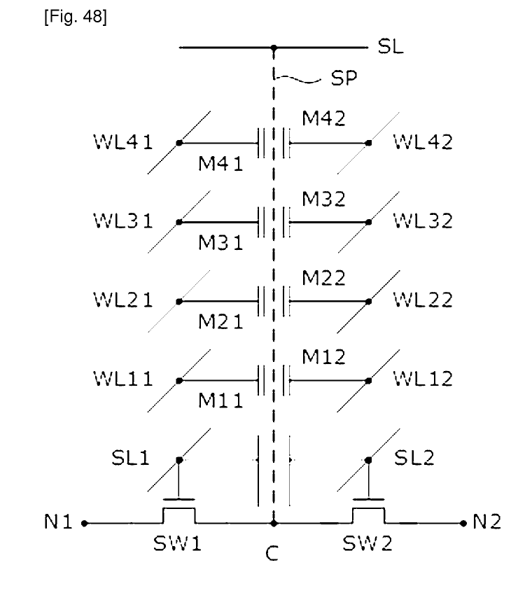

Furthermore, as shown in FIG. 48, the first and second selection lines SL1 and SL2 may be disposed opposite the semiconductor pattern SP to constitute MOS capacitors. That is, the electrical connection of the semiconductor pattern SP with the connection node C may be controlled by a voltage applied to the first or second selection line SL1 or SL2.

As a result, the first and second selection lines SL1 and SL2 may be used not only as electrodes of switching elements for controlling the node selection operation but also electrodes of MOS capacitors for controlling the cell selection operation. According to some embodiments, a voltage (hereinafter, a voltage V1) applied to the selection line, which is required for the node selection operation (i.e., horizontal connection), may differ from a voltage (hereinafter, a voltage V2) required for the cell selection operation (i.e., vertical connection). For example, the voltage V1 may be higher than the voltage V2.

More specifically, when a voltage equal to or higher than the voltage V1 is applied to the first selection line SL1, a voltage of the first node N1 can be transmitted to the connection node C. Here, if a voltage lower than the voltage V1 and higher than the voltage V2 is applied to the second selection line SL2, the voltage of the first node N1 can be transmitted to the connection node C and thereafter, it may be transmitted to a selected memory cell through the semiconductor pattern SP. But it cannot be transmitted to the second node N2, and vice versa. The above-described method of controlling the current path may be employed to select one of memory cells disposed on both sides of one semiconductor pattern SP as described later.

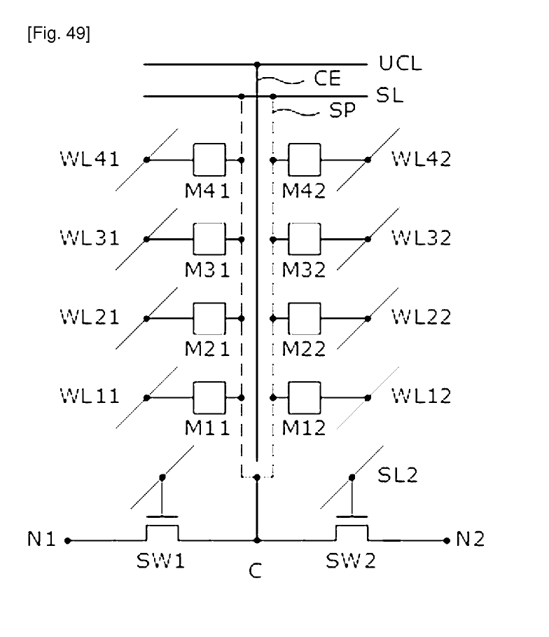

Meanwhile, as shown in FIG. 49, a control electrode CE connected to the upper control line UCL may be inserted into the semiconductor pattern SP to control the electrical potential of the semiconductor pattern SP. The upper control line UCL and the control electrode CE may have the same technical features as described with reference to FIGS. 22 to 43. According to the present embodiments, the above-described horizontal connection may be controlled by the voltages applied to the first and second selection lines SL1 and SL2, and the above-described vertical connection may be controlled by the voltage applied to the control electrode CE.

Meanwhile, as shown in FIGS. 47 through 49, a source line SL may be connected to the other end portion of the semiconductor pattern SP. As a result, the semiconductor pattern SP may serve as a path for an electrical connection between the connection node C and the source line SL. The semiconductor pattern SP may include a rectifying element formed adjacent to at least one of the source line SL and the connection node C. For example, the semiconductor pattern SP may include regions of different conductivity types to constitute at least one diode.

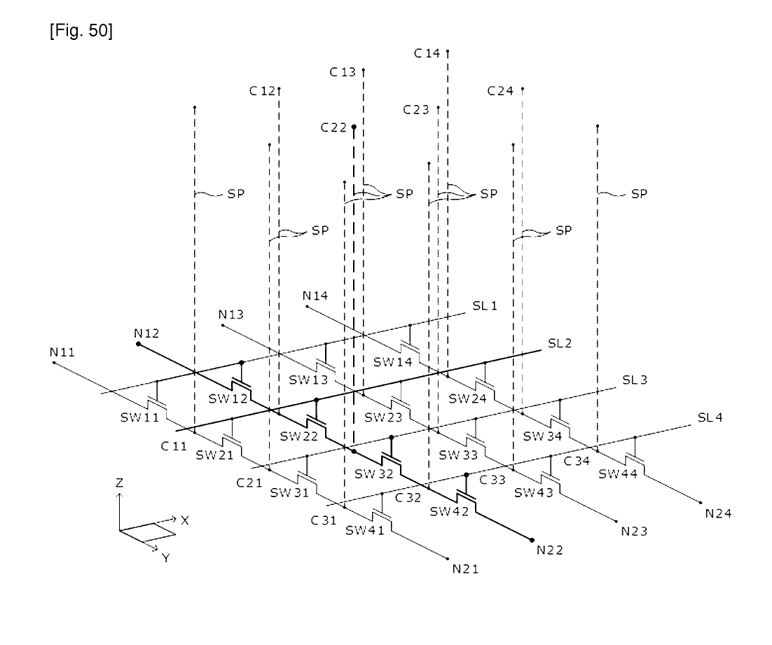

FIGS. 50 through 52 are circuit diagrams of a cell array of a semiconductor device including the above-described switching elements, which schematically illustrate technical features related with xy-, xz-, and yz-planes, respectively. For brevity, a description of the above-described technical features will be omitted.

Referring to FIGS. 50 to 52, a plurality of connection nodes Cij may be two-dimensionally arranged on the xy-plane (Although the connection nodes Cij are regions interposed between switching elements, it should be noted that some of labels of the connection nodes Cij are shown at upper regions of the drawings in order to reduce complexity of drawings). The connection nodes Cij may constitute a plurality of node strings connected between first nodes N11, N12, N13, and N14 and second nodes N21, N22, N23, and N24. The respective node strings may have different x-coordinates and include connection nodes Cij having different y-coordinates and substantially the same x-coordinate.

Semiconductor patterns SP having a z-directional major axis may be connected to the respective connection nodes Cij, and x-lines Lij having an x-directional major axis may be three-dimensionally arranged between the semiconductor patterns SP. That is, a plurality of x-lines Lij may be two-dimensionally arranged on each of the xz-planes between the semiconductor patterns SP. Memory elements may be disposed between the x-lines Lij and the semiconductor patterns SP. Although a charge storage layer is exemplary illustrated as the memory element, the memory elements may be at least one of the charge storage layer, a phase-change layer, and an MR element.

Switching elements SWij may be arranged between the connection nodes Cij to control the electrical connection therebetween (i.e., the node selection operation). The switching elements SWij may be two-dimensionally arranged on the xy-plane and control the electrical connection between the connection nodes Cij, which are included in the same node string and have different y-coordinates. The switching elements SWij may be metal-oxide-semiconductor field-effect transistors (MOSFETs) whose switching operations are controlled by selection lines SL1-SL4 having major axes along the x-direction. In addition, as explained above, the selection lines SL1-SL4 may be disposed opposite the semiconductor pattern SP to constitute MOS capacitors for controlling the cell selection operation or the vertical connection. In this case, as stated above, the voltage V1 for the node selection operation may differ from the voltage V2 for the cell selection operation.

Meanwhile, first and second bit lines (not shown) may be coupled to the first and second nodes Nij. At least one of the bit lines may have a major axis crossing the x-lines Lij and connect the first and second nodes Nij. The bit line may have the same technical feature as in the embodiments explained with reference to FIGS. 22 through 43, and other technical features related to the bit line will be further explained with reference to FIGS. 60 through 62. In addition, the other end portions of the semiconductor patterns may be coupled to a specific source line S/L, as explained with reference to FIGS. 47 through 49. Here, the source line S/L may have a major axis parallel to or across a major axis of the x-line. According to a modified embodiment, without any additional source line, two selected out of the bit lines may constitute a bit line and a source line, respectively.

The semiconductor pattern SP may include a body portion, which may be disposed adjacent to the memory cells, and a connecting portion, which may be formed in the body portion or at least one of both ends of the body portion. Here, the connection portion and the body portion may have different conductivity types to constitute a rectifying element. At least one of the x-lines may be disposed opposite the body portion and control an electrical connection between the body portion and the connection portion. For example, a voltage applied to the x-lines may result in inversion of the adjacent body portion, thereby enabling an electrical connection between the connection portion and a predetermined memory cell. Alternatively, the voltage applied to the x-lines may prevent inversion of the adjacent body portion, thereby enabling a selective disconnection between the connection portion and the body portion.

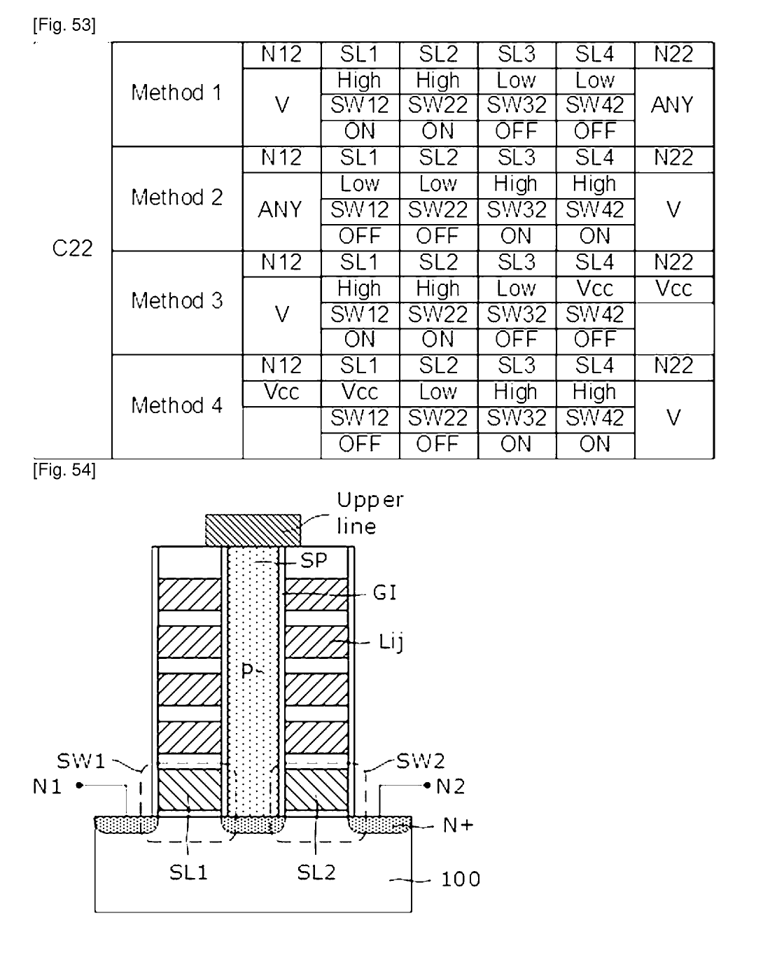

FIG. 53 is a table for explaining a method of operating a 3D semiconductor device according to exemplary embodiments of the present invention (specifically, node selection operation).

Referring to FIG. 53, a target connection node (e.g., C22) may be connected to a selected node (e.g., N12). The connection between the target connection node C22 and the selected node N12 may be enabled by applying a voltage equal to or higher than a threshold voltage of the switching element to selection lines SL1 and SL2 between the selected node N12 and the target connection node C22 to turn on the switching elements connected to the selection lines SL1 and SL2. Meanwhile, the target connection node C22 may be electrically isolated from an unselected node N22. As shown in Methods 1 and 2 of FIG. 53, the isolation of the target connection node C22 from the unselected node N22 may be enabled by turning off switching elements SW32 and SW42 disposed between the unselected node N22 and the target connection node C22. In another method, as shown in Methods 3 and 4 of FIG. 53, the isolation of the target connection node C22 from the unselected node N22 may be enabled by pinching off a transistor disposed adjacent to the unselected node N22. Since the way of pinch-off is presently used as a known method for self-boosting a NAND flash device, a further description thereof will be omitted.

A point on the xy-plane including connection nodes is selected by the foregoing node selection operation. In other words, x- and y-coordinates in 3D space are bound by coordinate-constraints due to the node selection operation, and only one coordinate (i.e., z-coordinate) has a degree of freedom. The operating method according to the present invention may further include a cell selection operation for bounding the z-coordinate.

The cell selection operation may be enabled by applying a voltage enabling inversion of the semiconductor pattern SP to the x-lines disposed between a target memory cell (or a selected memory cell) and a node selected during the node selection operation. In this case, inversion regions formed by the x-lines should be overlapped with each other so that the inversion regions can be connected to the target memory cell. In order to satisfy this condition, a vertical interval between the x-lines may be narrower than twice the width of the inversion regions. According to a modified embodiment, a selection line disposed under the target memory cell may also participate in the cell selection operation using the method described with reference to FIG. 48.

Meanwhile, according to the above-described embodiments, one semiconductor pattern may be used as a common path for accessing memory cells having different y-coordinates. However, since an electrical connection of the selected connection node with the selected memory cell is enabled by the x-lines included in the same word line structure as the selected memory cell, an electrical connection between the selected connection node and an unselected memory cell can be interrupted. For example, when at least one of voltages applied to the x-lines disposed between the unselected memory cell and the selected connection node is equal to or lower than the threshold voltage or floated, the unintended connection can be interrupted.

As a result, data storing layers formed on both sidewalls of one x-line may serve as places capable of storing data independently. That is, the semiconductor device according to the above-described embodiments may have a bit number per area, which doubles that of a semiconductor device in which data storing layers formed on both sidewalls of one x-line do not serve as places for storing data independently.

Write (i.e., program and erase) and read operations of a memory cell may be performed using the above-described node selection operation and cell selection operation. Since the write and read operations may be realized using known methods of operating memory semiconductor devices and modifications thereof, a detailed description thereof will be omitted for brevity. For example, the technical features according to the present invention may be employed to realize a cell array of a NAND-type flash memory device. In this case, those skilled in the art may make attempt to further apply string or ground selection transistors to the semiconductor device based on descriptions disclosed in known documents.

FIGS. 54 through 59 are cross-sectional views of 3D semiconductor devices according to exemplary embodiments of the present invention.

Referring to FIG. 54, the switching elements SWij may be MOSFETs formed on a substrate 100. The connection nodes Cij may be impurity regions N+ used as source and drain electrodes of the MOSFETs, and the semiconductor pattern SP may be a region extended from the impurity region N+. Here, the semiconductor pattern SP may have a different conductivity type from the impurity region N+.

The x-lines Lij may be sequentially stacked on selection lines SL1 and SL2 used as gate electrodes of the MOSFETs. According to one exemplary embodiment, the selection lines SL1 and SL2 and the x-lines Lij may constitute word line structures, which are formed using a one-time patterning process. In this case, the selection lines SL1 and SL2 and the x-lines Lij may have substantially aligned sidewalls. Since the selection lines SL1 and SL2 constitute MOS capacitors along with the semiconductor patterns SP, the selection lines SL1 and SL2 may serve as electrodes for controlling the vertical connection or the cell selection operation as described with reference to FIG. 48.

An interval between the selection lines SL1 and SL2 and the x-lines Lij may be selected within such a range as to enable overlapping of the inversion regions. A gate insulating layer GI, which may serve as a data storing layer or charge storage layer, may be interposed between the semiconductor pattern SP and the x-lines Lij. An upper interconnection line may be disposed on and connected to an upper region of the semiconductor pattern SP. The upper interconnection line may be used as a bit line or source line. For example, at least one of the first and second nodes N1 and N2 may be connected to the upper interconnection line through the semiconductor pattern SP.

Meanwhile, the semiconductor pattern SP may have a single crystalline structure, a polycrystalline structure, or an amorphous crystalline structure. According to an exemplary embodiment, the semiconductor pattern SP may be formed of silicon that is grown from the substrate 100 using an epitaxial process.

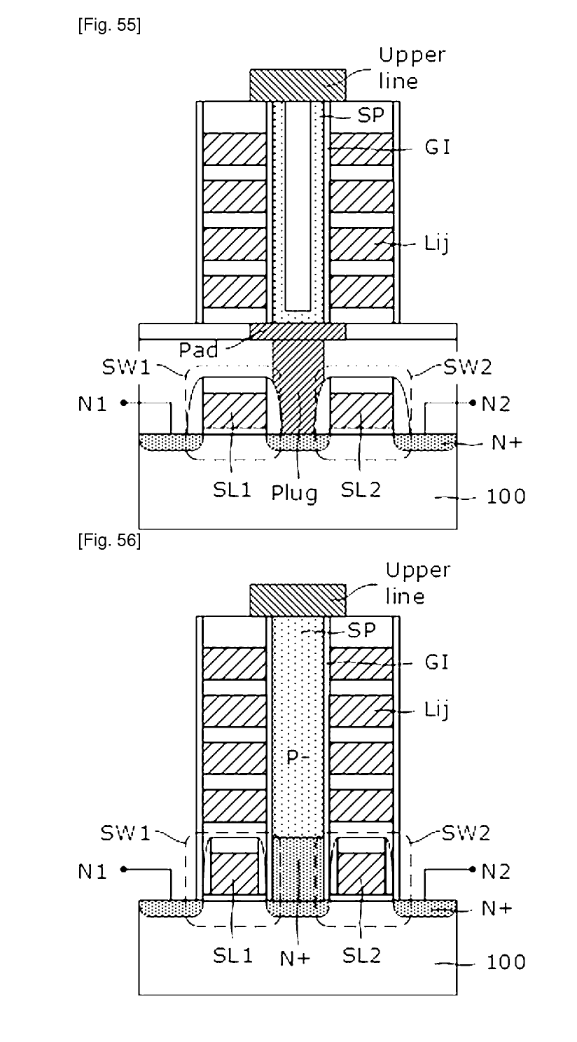

According to another exemplary embodiment, as shown in FIG. 55, the semiconductor pattern SP may be formed on a plug and/or pad connected to the connection node Cij. In this case, the cell selection operation may be performed irrespective of a voltage applied to the selection lines SL1 and SL2. Also, according to the present embodiment, the semiconductor pattern SP may be formed using a CVD or ALD technique to conformably cover spaces between the word line structures, as shown in FIG. 55.

According to yet another embodiment, as shown in FIG. 56, a lower region of the semiconductor pattern SP disposed adjacent to the selection lines SL1 and SL2 may have the same conductivity type as the connection node Cij such that the cell selection operation may be performed irrespective of the voltage applied to the selection lines SL1 and SL2. In this case, the selection lines SL1 and SL2 may be formed separately from the x-lines Lij using different patterning processes.

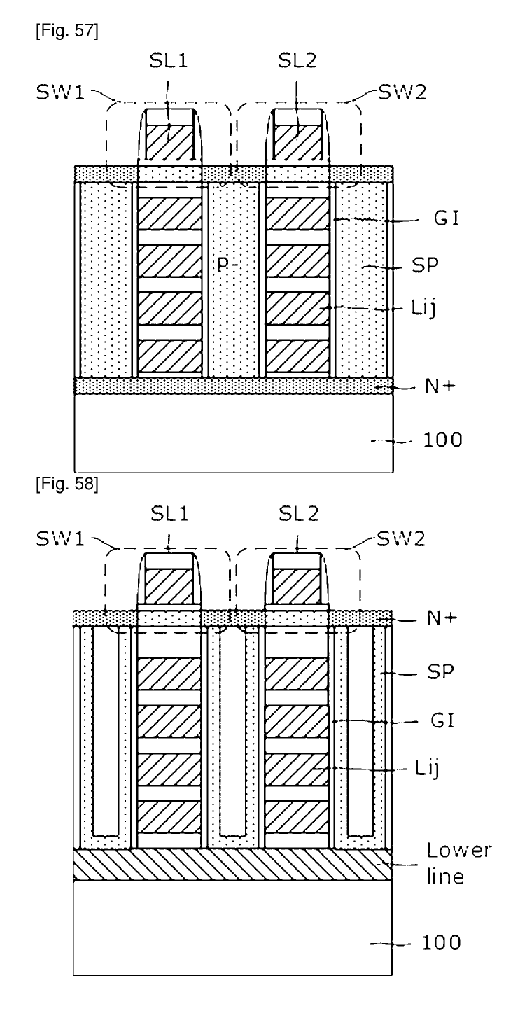

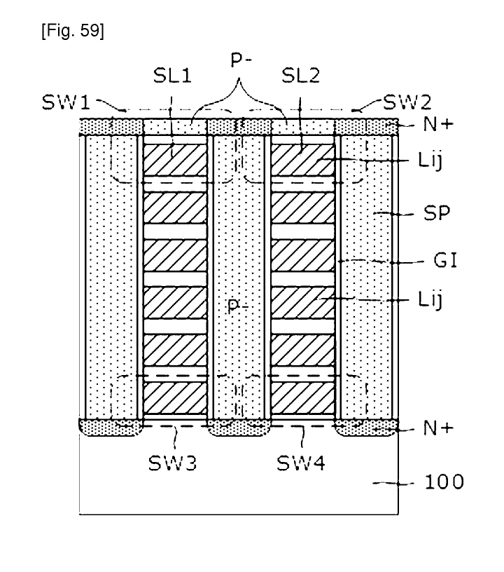

As shown in FIGS. 57 and 58, the switching elements SWij may be formed over the word line structures. To do this, a semiconductor layer having regions of different conductivity types may be formed over the word line structure. The semiconductor layer may be formed of at least one selected from the group consisting of Group IV materials, Group III-V materials, organic semiconductor materials, and carbon nano-structures using one of a vapor deposition technique, a wafer bonding technique, and an epitaxial technique using the semiconductor pattern as a seed. In this case, although the selection lines SL1 and SL2 may be formed on the semiconductor layer as shown in FIGS. 57 and 58, the selection lines SL1 and SL2 may be the uppermost one of the x-lines as shown in FIG. 59.

As shown in FIGS. 57 and 58, the lower region of the semiconductor pattern SP may be connected to a lower interconnection line that sequentially connect a plurality of semiconductor patterns. The lower interconnection line may be an impurity region formed in a conductor or a substrate. Alternatively, as shown in FIG. 59, the switching elements SWij may be formed over and under the word line structure. An increase in the number of the switching elements SWij may lead to an increase in the number of current paths that can be realized.

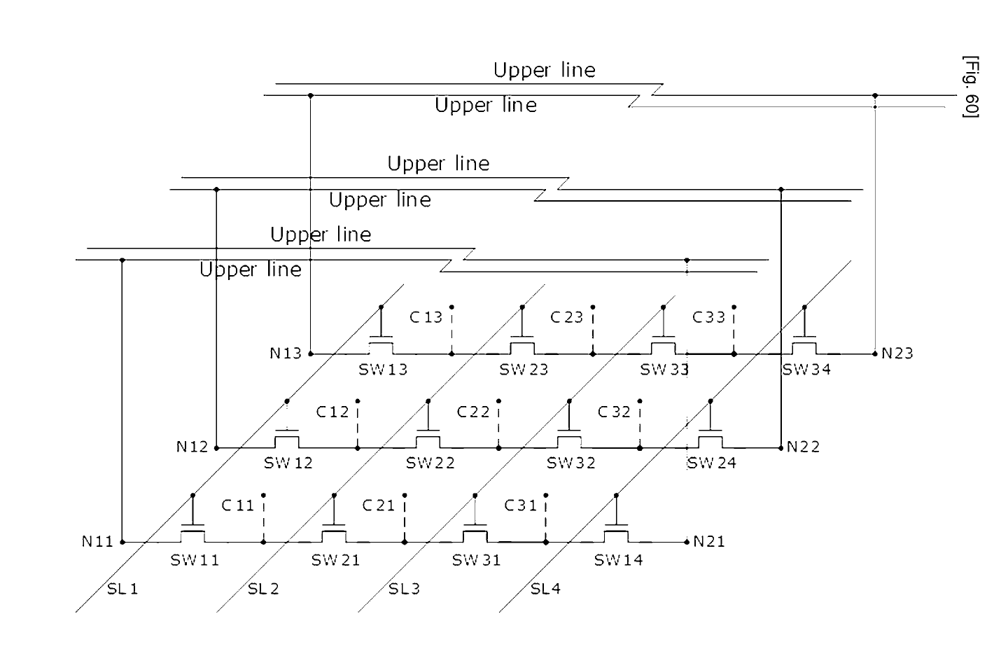

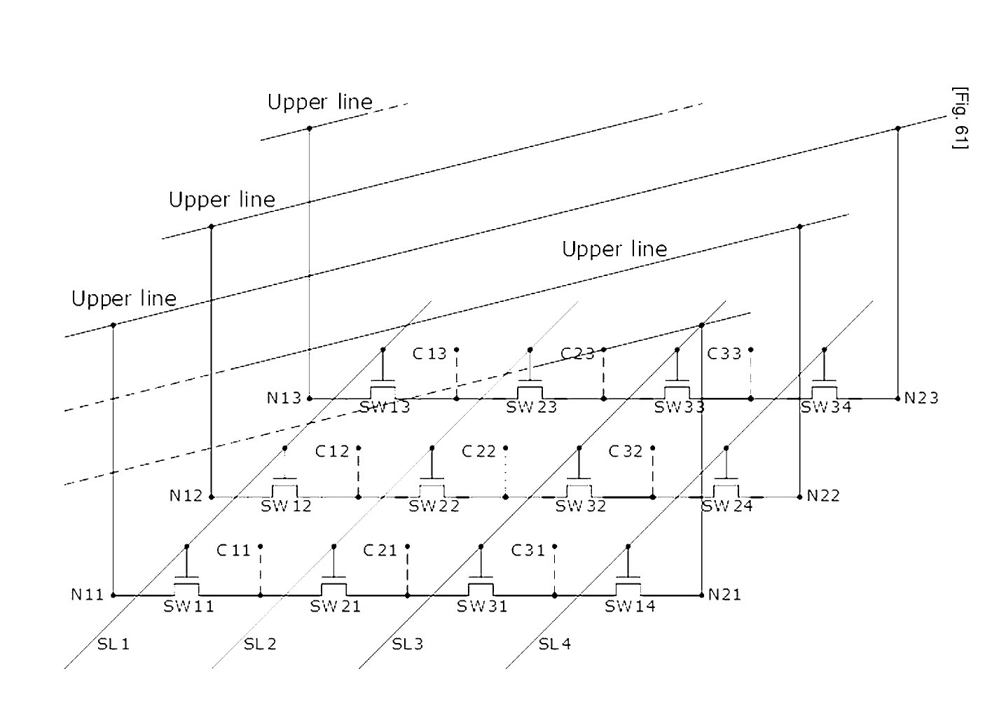

According to some exemplary embodiments of the present invention, different voltages may be applied to first and second nodes included in one node string. To do this, as shown in FIG. 60, an upper interconnection line that connects the first nodes may differ from an upper interconnection line that connects the second nodes. Alternatively, as shown in FIG. 61, the upper interconnection lines may cross over the node strings aslant to the node strings. In this case, the first and second nodes connected to one upper interconnection line may differ on all the x- and y-coordinates. According to another exemplary embodiment, the upper interconnection lines may intersect the node strings aslant to the node strings like in FIG. 61, and also connect the semiconductor patterns as shown in FIG. 62. According to the present exemplary embodiment, a plurality of adjacent semiconductor patterns SP, which are included in one node string, may be connected to different upper interconnection lines, respectively.

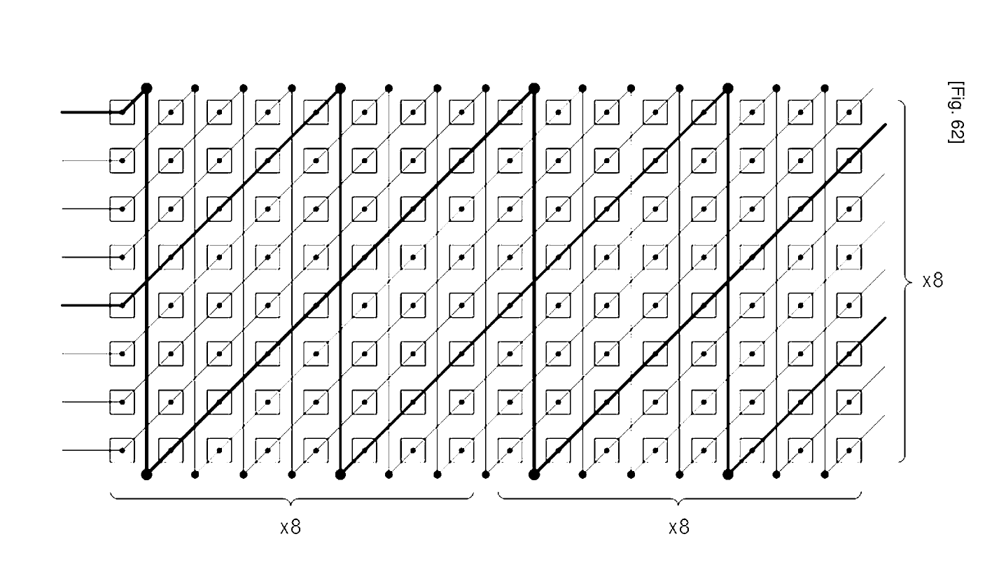

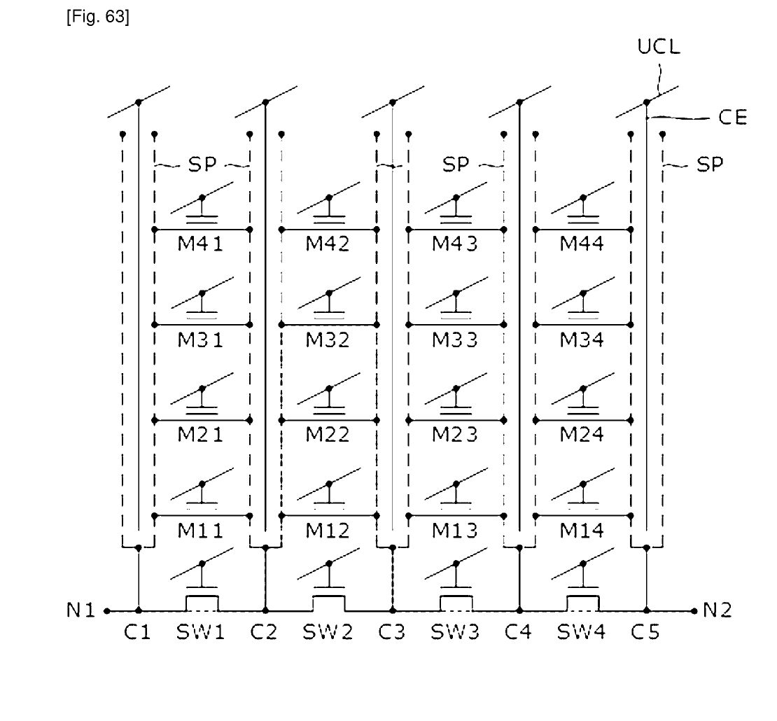

FIGS. 63 through 65 illustrate NOR-type cell array structures according to the present invention.

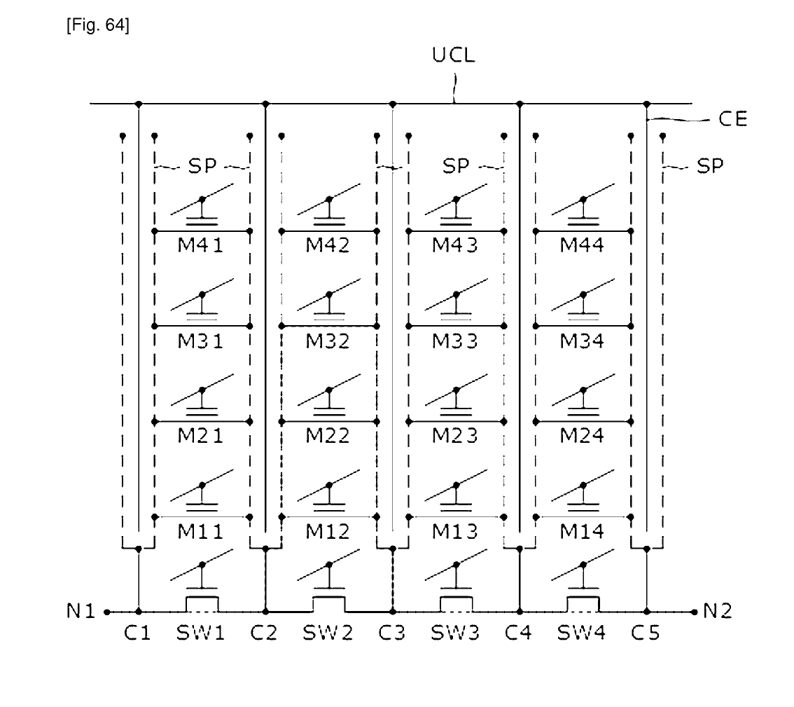

As shown in FIGS. 63 and 64, a NOR-type cell also may include a control electrode and an upper control line, which are disposed opposite a semiconductor pattern to control a vertical connection. The upper control line UCL may be disposed parallel to or across the x-lines Lij. A current path may be formed to pass through the switching elements between the first and second nodes and a selected memory cell (e.g., M32), as shown

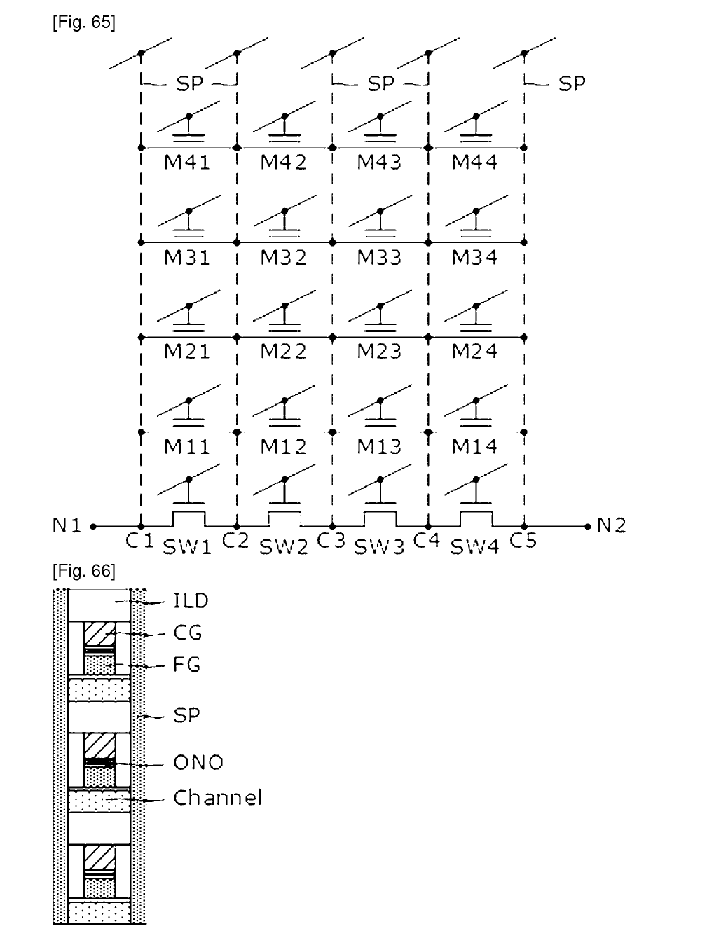

When the control electrode CE is not required to form the current path passing through the semiconductor pattern SP, a NOR-type cell array structure may be configured as shown in FIG. 65. However, as shown in FIG. 66, in the case of NOR-type FLASH memory device, a current path passing through the semiconductor pattern SP may be incompletely formed by voltages applied to control gates CG. In this case, as shown in FIGS. 63 and 64, it may be necessary to complete the current path using the control electrode CE. In the meantime, in the memory cell structures of FIGS. 44 and 66, since the horizontal channel region 80 or the channel region has a different conductivity type from the semiconductor pattern SP, the horizontal channel region 80 or the channel region may be used as a charge storage region. In this case, such semiconductor device may be used as a capacitorless DRAM or Unified RAM for Multi-Functioning DRAM and NVM.

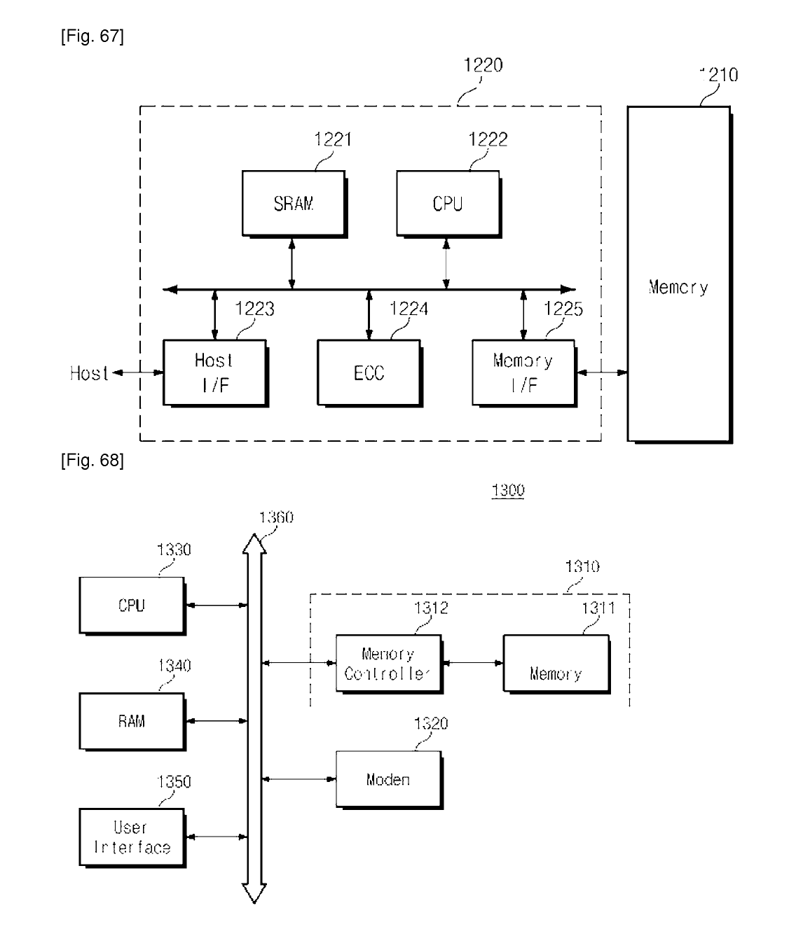

FIG. 67 is a block diagram illustrating one example of a memory card 1200 including a flash memory device according to the present invention. Referring to FIG. 67, the memory card 1200 that supporting high data storage capacity includes a flash memory device 1210 according to the present invention. The memory card 1200 according to the present invention includes a memory controller 1220 that controls the whole data exchange between a host and the flash memory device 1210.

An SRAM 1221 is used as an operation memory of a processing unit 1222. A host interface 1223 includes a data exchange protocol of the host connected to the memory card 1200. An error correction block 1224 detects and corrects an error in data read from the multi-bit flash memory device 1210. A memory interface 1225 interfaces with the flash memory device 1210 of the present invention. The processing unit 1222 performs the whole control operation to exchange data of the memory controller 1220. Although not shown, it is obvious to those skilled in the art that the memory card 1200 according to the present invention may further include a ROM (not shown) storing code data for interfacing with the host.

According to other embodiments of the present invention, the semiconductor device of the present invention described with reference to FIGS. 1 through 66 can be provided to realize a memory system such as a solid-state disk (SSD).

FIG. 68 is a block diagram of a data processing system 1300 with a flash memory system 1310 mounted according to the present invention. Referring to FIG. 68, the flash memory system 1310 of the present invention is mounted on the data processing system such as a mobile apparatus and a desktop computer. The data processing system 1300 according to the present invention includes the flash memory system 1310, a modem 1320 electrically connected to a system bus 1360, a central processing unit (CPU) 1330, a RAM 1340, a user interface 1350. The flash memory system 1310 may have the same configuration as the aforesaid memory system or flash memory system substantially. Data processed by the CPU 1330 or data input from the outside are stored in the flash memory system 1310. Herein, the flash memory system 1310 may be implemented into a solid-state disk (SSD). In this case, the data processing system 1300 can store large data in the flash memory system 1310. According to an increase in reliability, the flash memory system 1310 can reduce resources required for error correction to thereby provide high-speed data exchange function to the data processing system 1300. Although not shown, it is obvious to those skilled in the art that the data processing system 1300 according to the present invention may further include an application chipset, a camera image processor (CIS), an input/output unit.

Further, the flash memory device or the memory system according to the present invention can be packaged in various forms. For example, the flash memory device or the memory system according to the present invention may be packaged and mounted in such a manner as package on package (PoP), ball grid arrays (BGAs), chip scale packages (CSPs), plastic leaded chip carrier (PLCC), plastic dual in-line package (PDIP), die in waffle pack, die in waver form, chip on board (COB), ceramic dual in-line package (CERDIP), plastic metric quad flat pack (MQFP), thin quad flatpack (TQFP), small outline (SOIC), shrink small outline package (SSOP), thin small outline (TSOP), thin quad flatpack (TQFP), system in package (SIP), multi chip package (MCP), wafer-level fabricated package (WFP), and wafer-level processed stack package (WSP).

FIGS. 69 and 70 are cross-sectional views of a 3D phase-change memory device according to exemplary embodiments of the present invention. Technical features according to the present exemplary embodiments may be applied to the embodiments described with reference to FIGS. 22 through 45, 49, 63, 64, 69, and 70.

Referring to FIG. 69, a method of operating a semiconductor device including the control electrode CE may include inverting the semiconductor pattern SP connected in parallel to a plurality of information storage elements ISE using a voltage applied to the control electrode CE. Access or electrical connection to a specific memory cell can be enabled when the inverted region expands to the information storage elements ISE or the additional conductor (or heater). To enable this electrical connection, a thickness D1 of the semiconductor pattern SP is required to be smaller than a width of the inverted region (i.e., a distance of the inverted region measured from the control gate insulating layer CGI). Here, the width of the inverted region may be controlled by changing a material and dopant concentration of the semiconductor pattern SP and the thickness of the control gate insulating layer CGI.

Meanwhile, when the information storage element ISE is a phase-change layer as shown in FIG. 69, an additional conductor functioning as a heater electrode may be further formed between the information storage element ISE and the semiconductor pattern SP. The formation of the heater electrode may include selectively etching the patterned sidewall of the information storage element ISE to form a recess region between the ILDs 61, forming a heater layer to fill the recess region, and etching the heater layer to separate the heater layer into heater electrodes.

According to other exemplary embodiments, after forming the heater electrodes, sidewalls of the ILDs 61 may be further etched until one end portions of the heater electrodes protrude. Thus, as shown in FIG. 70, a distance D2 between the control gate insulating layer CGI and the heater electrode may be smaller than a distance D1 of the semiconductor pattern SP. In this case, a distance D2 between the control gate insulating layer CGI and the heater electrode may be smaller than the width of the region inverted by the voltage applied to the control electrode CE.

Meanwhile, in the current paths described with reference to FIG. 41, since two different semiconductor patterns SP are connected to one information storage element ISE, such two contact regions of the information storage element ISE, as shown in FIGS. 69 and 70, may be used as two independent memory regions MR1 and MR2.

### INDUSTRIAL APPLICABILITY

Exemplary embodiments of the present invention may be used to realize a 3D memory semiconductor device.

1-63. (canceled)

64. A memory device comprising:
a connection node disposed on a predetermined plane;
a semiconductor pattern coupled to the connection node;
a plurality of conductive lines crossing the semiconductor pattern;
a plurality of memory elements, each memory element disposed between the semiconductor pattern and the corresponding one of the conductive lines; and
a control electrode facing the semiconductor pattern,
wherein an electrical connection between the connection node and one of the memory elements is controlled by the control electrode.

65. The device of claim 64, wherein the semiconductor pattern has a major axis penetrating through the plane, and distances from the plane to the conductive lines are different from each other.

66. The device of claim 64, wherein the control electrode has a major axis penetrating through the plane.

67. The device of claim 64, wherein the semiconductor pattern is coupled to the connection node through a rectifying element, and an electrical connection between the connection node and one of the memory elements is selectively realized by a voltage applied to the control electrode.

68. The device of claim 64, wherein the memory element includes one of variable resistance elements, magneto-resistive elements or charge storing elements, which is serially connected between the semiconductor pattern and the conductive line.

69. The device of claim 64, wherein the control electrode and the semiconductor pattern are spaced apart from each other, thereby constituting a capacitor.

70. The device of claim 64, wherein the connection node and the semiconductor pattern constitute a diode.

71. A memory device comprising:
connection nodes disposed two-dimensionally on a predetermined plane;
semiconductor patterns, each semiconductor pattern coupled to the corresponding one of the connection nodes and having major axis penetrating through the plane;
conductive lines disposed three-dimensionally to cross the semiconductor patterns;
memory elements disposed between the conductive lines and the semiconductor patterns; and
control electrodes, each control electrode facing the corresponding one of the semiconductor patterns,
wherein the connection nodes includes a selected connection node, the semiconductor patterns includes a selected semiconductor pattern coupled to the selected connection node, the memory elements includes a selected memory element coupled to the selected semiconductor pattern, and the control electrodes includes a selected control electrode facing the selected semiconductor pattern,
wherein the selected control electrode is configured to control selectively an electric connection between the selected connection node and the selected memory element.

72. The device of claim 71, wherein the semiconductor pattern is coupled to the connection node through a rectifying element, and an electrical connection between the connection node and one of the memory elements is selectively realized by a voltage applied to the control electrode.

73. The device of claim 71, wherein the memory element includes one of variable resistance elements, magneto-resistive elements or charge storing elements, which is serially connected between the semiconductor pattern and the conductive line.

74. The device of claim 71, further comprising at least one conductive line coupled to the semiconductor pattern,
wherein each of the semiconductor patterns is disposed between the connection node and the conductive line to form a current path therebetween.

75. The device of claim 71, wherein the control electrode has a major axis penetrating through the plane.

76. The device of claim 71, wherein the control electrode and the semiconductor pattern are spaced apart from each other, thereby constituting a capacitor.

77. The device of claim 71, wherein the connection node and the semiconductor pattern constitute a diode.
